(19) United States
(12) Patent Application Publication
(10) Pub. No.: US 2025/0158437 A1
(43) Pub. Date: May 15, 2025

(54) INTELLIGENT BATTERY MANAGEMENT SYSTEM AND METHOD

(71) Applicant: BREATHE BATTERY TECHNOLOGIES LIMITED, London Greater London (GB)

(72) Inventors: Ian CAMPBELL, London Greater London (GB); Yan ZHAO, London Greater London (GB); Jingyi CHEN, London Greater London (GB)

(21) Appl. No.: 18/836,474

(22) PCT Filed: Feb. 6, 2023
(86) PCT No.: PCT/GB2023/050256

§ 371 Date: Aug. 7, 2024

(30) Foreign Application Priority Data
Feb. 7, 2022 (GB) 2201552.3

(51) Int. Cl. H02J 7/00; G01R 31/367; G01R 31/388; G01R 31/392

(52) U.S. Cl. CPC H02J 7/007182; G01R 31/367; G01R 31/388; G01R 31/392; H02J 7/0048; H02J 7/005; H02J 7/00714; H02J 7/007194

(57) ABSTRACT

An intelligent battery management system and method, and in particular a battery management system utilizing a method for the estimation of the instantaneous positive and negative electrode potentials used during a battery charging/discharging process. The intelligent battery management system and method may be used in a battery control system, such as a battery charging/discharging system to preserve the health of a connected battery over multiple cycles, or in a battery diagnostic system for predicting or modelling battery performance. During a battery charging/discharging process, one or more set points may be set for the electrode potentials on the negative and or positive electrodes. Using the battery overpotential in the determination of electrode potential, allows the battery management method and system to exhibit a high level of adaptivity to battery ageing and battery degradation.

### FIELD OF THE INVENTION

The present invention relates to an intelligent battery management system and method, and in particular to a battery management system utilising a method for the estimation of electrode potentials. The intelligent battery management system and method may be used in a battery control system, such as a battery charging/discharging system to preserve the health of the battery over multiple cycles, or in a battery diagnostic system for predicting or modelling battery performance.

### BACKGROUND OF THE INVENTION

Society is observing a shift away from combustion as a source of energy. Solar panels connected to batteries can now power and heat our homes, while batteries in vehicles now provide either the main or auxiliary means of propulsion. Although still at an early stage, batteries are predicted to play an ever more vital role in decarbonising the aviation industry. Similarly, with renewables taking up an ever increasing share of national electricity generation, electricity distribution grids need to provide higher levels of battery storage capacity to stabilise supply when the sun is not shining or the wind is not blowing. At the same time, batteries continue to power our home electronics and electrical appliances. As battery applications proliferate, it is increasingly important that the energy and resource cost of batteries be minimised, and that individual battery health and lifetime be maintained. Degradation in a battery's health can lead to a reduction in both performance and safety.

Degradation of battery health occurs over time and with battery usage, often leading to reduced capacity, increased resistance, and/or other effects. The rate and extent of degradation is dependent upon multiple factors, with one specific factor being the potential of the electrodes within the battery. For example, a widely known degradation process results from low levels of electrode potential in lithium-ion intercalation batteries with graphitic negative electrodes, leading to the undesirable deposition of metallic lithium (“lithium deposition”) on the graphite electrode. Another example is the possible oxidation of metallic current collectors at low potentials, or the reaction between an electrode and an electrolyte at high potentials, which may lead to gassing and thus pose a safety risk.

To avoid the above-mentioned degradation and safety concerns, and in an effort to maintain battery state-of-health and safety as high as possible for as long as possible, it is typical when operating batteries to carefully control the cell terminal potential. The cell terminal potential is the difference in potential between a cell's positive and negative electrodes, and hereafter will simply be referred to as “cell potential” or “battery potential”. Further, as will be described later, such potentials are typically expressed with respect to a predefined reference potential, such as the potential of lithium metal.

Additionally, in this regard the term ‘battery’ may also be understood to refer to either a single battery cell, a battery module (a group of cells connected together) or a battery packs (a group of modules connected together). Battery terminal voltage (or potential) and battery terminal current can be measured on either a cell, a module or a pack. Throughout this document, references to cell potential, cell current or cell temperature, may therefore be understood to refer to a single cell or to the corresponding measurements made on a battery comprising a plurality of cells connected as modules or packs.

Although it would be preferable to know the values of the negative and positive electrode potentials, only the cell potential of the battery is usually used in battery control applications. This is because the cell potential indirectly controls the potentials of the positive and negative electrodes, and because unlike the negative electrode and positive electrode potentials, the cell potential can be easily measured. Direct measurement of the individual negative or positive electrodes potentials, for example, would require the battery to be provided with a separate reference electrode, which is presently only feasible on test rigs. Commercially available batteries do not provide a reference electrode for the measurement to take place.

Although computational methods may be used to estimate the negative and positive electrode potentials, such methods are often both complicated and resource intensive, and for reasons discussed below, predict the potentials with only a limited amount of certainty.

Conventionally, there are two approaches to obtaining the electrode potentials in full-cells: first, experimentally, using a reference electrode inserted into a full-cell (this is common in research communities but highly uncommon in commercially available cells because of associated difficulties with maintaining cell stability and increased cost); and, second, via state estimation using modelling and simulation, wherein mathematical models are used to estimate the electrode potentials.

However, there is considerable difficulty in predicting the values of the positive and negative electrode potentials with the required degree of confidence, such that the values may be used for battery control purposes and/or as information that is useful in understanding the battery's state-of-health. First, the open-circuit potentials of the electrodes and of the cell (the open-circuit potential is the equilibrium potential of either a battery or a material such as the positive or negative electrode) varies with other parameters such as state-of-charge, temperature, and the degradation or health of the battery. Secondly, both the cell and electrode potentials deviate from their open-circuit potentials under the application of a load (e.g. during battery charging or discharging), or following the removal of a load during a relaxation process where the potential converges towards the open-circuit value but requires time to reach it. As a result, predicting the negative or positive electrode potentials using state estimation methods carries a number of disadvantages, including one or more of computational cost, low stability and parameterisation difficulties.

High computational cost is due to a large amount of computer memory or processing power being required to perform the estimation. For example, electrochemical “full-order” continuum battery models have the capability to estimate electrode potentials, but rely on solving differential equations that describe temporal (and sometimes also spatial) variations in the concentration of electrochemical species (e.g. lithium) and the potentials of battery components (e.g. electrodes, electrolyte). An example of such a model for a rechargeable lithium-ion intercalation battery is the pseudo-two-dimensional model, relying on four partial differential equations for the description of lithium species concentrations and electric potentials, plus an analytical equation describing the relation between overpotential and lithium flux into or from the energy-storing electrode host materials. The high computational cost of solving such equations increases the associated monetary cost of the solution, as well as the size of the requisite hardware, thereby limiting the applicability of the state estimation approach and ruling out the option of implementing it on an embedded system such as a low-cost microcontroller target. Further, resulting models can often be insufficiently fast for real-time use.

Low stability is a further consideration as the numerical solutions sought by computational methods operating on the differential equations are not always stable. Convergence failures can occur in which no solution is found, or if the method converges to a solution value far away from reality. Unreliable methods could not be used in embedded applications where real-time and safety-critical control decisions may be being made based upon the estimated states.

Parameterisation difficulties include parameterisation cost and parameterisation complexity. Commonly, those battery models which are sufficiently complex to include electrode potentials as states also require data for a large number of battery parameters to be obtained for their use. Examples of such parameters in a full-order electrochemical model include electrolyte and electrode phase species (lithium) diffusivities, averaged electrode particle radii, electrode porosities and non-constant parameters such as the electrolyte conductivity as a function of salt concentration. This increases the time and cost of preparing the model for use with any given battery, because a large number of experimental studies are needed to obtain the battery parameters. Furthermore, it increases the difficulty of maintaining an accurate model as the battery degrades throughout its lifetime, because parameter values will need to be updated with a battery's evolving state-of-health. An example, is electrode porosity which is known to decrease with the build-up of products from parasitic side reactions. It is not currently possible to update many such parameters without cell disassembly, which of course is not conducive to continued use of the battery.

Remedies to all of these issues can be sought with reduced-order modelling involving simplified versions of full-order electrochemical models. However, even for reduced order modelling, the computational resources required still often exceed those available in embedded commercial hardware solutions, and the high parameterisation burden remains. Moreover, reduced-order approaches often introduce new shortcomings, such as a reduction in the accuracy of the state estimates at higher currents relative to those provided by full-order models.

We have appreciated that the widespread practice of using cell potential alone is unsatisfactory, because without direct control or even knowledge of the individual electrode potentials, one or both of the positive or negative electrode potentials may reach values that are detrimental to the battery state-of-health and/or to safety.

Further, we have appreciated that it would be desirable to provide an intelligent battery control method involving a real-time or predictive estimation of the individual negative and positive electrode potentials. The resulting estimates of electrode potential can advantageously be used to make battery control decisions, such as battery charging/discharging current, duration of charging/discharging processes, and/or other controllable parameters in the operation of a battery management system to maintain the health of the battery.

Further, the resulting estimates of electrode potential may be used in a diagnostic system to assess the present state-of-health of the battery, to determine the likelihood of future battery degradation, to support further battery development, to provide clarity and accountability for the battery warrantability, and to fulfil many other goals.

### SUMMARY OF THE INVENTION

The invention is defined in the independent claims to which reference is now made. Advantageous features are set forth in the dependent claims.

In a first aspect of the invention, a battery management method is provided for charging or discharging a connected battery, using calculated non-equilibrium potentials for one or more of the negative and positive electrodes of the battery, and one or more electrode potential set points; the battery management method comprising the steps of: determining for a connected battery one or more battery state parameters indicating the present state of the connected battery, the battery state parameters including one or more of the instantaneous battery potential, the battery current, and the battery temperature; receiving an indication of one or more electrode potential set points for the negative electrode potential and the positive electrode potential of the connected battery; determining an instantaneous negative electrode potential and an instantaneous positive electrode potential for the connected battery based on a determined state of charge for the connected battery and an over potential fraction map; wherein the overpotential fraction map maps respective state-of-charge values for a reference battery to the corresponding fractions of the battery overpotential that are attributable to the negative and the positive electrodes; controlling a charging/discharging current for the connected battery, or controlling a charging/discharging voltage for the connected battery based on the determined instantaneous negative electrode potential and the instantaneous positive electrode potential, such that the determined instantaneous negative electrode potential and the instantaneous positive electrode potential remain within a range of electrode potential operating values defined by the received indication of one or more electrode potential set points.

The battery management method uses an estimation of battery and electrode open-circuit potentials for the connected battery, combined with the battery overpotential fractions attributable to the negative and/or positive electrodes of the reference battery, to estimate the instantaneous electrode potentials for the connected battery. Using the battery overpotential in the determination of electrode potential allows the battery management method and system to exhibit a high level of adaptivity to battery ageing and battery degradation.

A corresponding system and computer program are also provided.

Conventional battery charging methods such as constants current-constant voltage (CC-CV) methods do not account for the current battery state. The battery's state is path-dependent, and varies with time and usage profiles. Real-time control according to the invention, based on battery state estimations, consider the battery state dynamically to regulate charging, discharging and storage. It is also important for fault diagnosis and hazard detection, which informs maintenance and replacement schedules.

Batteries are comprised of a positive electrode (PE), a negative electrode (NE) and an electrolyte. The physical processes that causes battery degradation and safety risks are better reflected in the characteristics and parameters of these components, rather than those that apply at the cell level. Hereby, the invention focusses on NE and PE potentials, and their variations with battery state of health (SOH) to implement real-time controls. The model parameters may be battery voltage, current and temperature, which are directly measurable.

This approach involves physical insights of the battery mechanisms, but remains computationally light to implement in real-time. The control framework is applicable to different cell chemistries and the control settings are tunable to different usage scenarios. Further, the state estimation of NE and PE potentials can assess the state of health (SOH), state of available power (SOAP) and reveal likely degradation mechanism, for example lithium plating on NE, structural instability on PE and particle cracking on both electrodes.

The method proposed is not limited to lithium ion batteries but is applicable for different types of batteries, in any case where PE and NE potentials are relevant.

### BRIEF DESCRIPTION OF THE DRAWINGS

Embodiments of the invention will be described by way of example and with reference to the drawings in which:

FIG. 1 illustrates a battery management system utilising a prediction of the non-equilibrium negative and/or positive electrode potential, according to a first example embodiment;

FIG. 2 illustrates a method for the determination of battery charging current using an estimate of non-equilibrium negative and/or positive electrode potential according to an embodiment of the invention;

FIG. 3 illustrates a reference open-circuit potential representation for a reference battery, and includes FIG. 3A which is a plot of the measured open-circuit potential for the reference battery against a state-of-charge measurement for the reference battery, and

FIGS. 3B and 3C which are the corresponding plots for the open-circuit potentials of the positive and negative electrodes of the reference battery;

FIG. 4 illustrates variations in the battery and electrode potentials illustrated in FIG. 3 in a polarised or non-equilibrium state, and includes FIG. 4A which is a plot of the measured non-equilibrium battery potential for the reference battery against a state-of-charge measurement for the reference battery in a charging/discharging process (two different charging currents (C-rates) are illustrated), and FIGS. 4B and 4C which are the corresponding plots for the electrode potentials of the positive and negative electrodes of the reference battery;

FIG. 5 illustrates the corresponding overpotential profiles, including FIG. 5A which is a plot of the corresponding overpotential profiles for the reference battery and for the two different charging currents (the overpotential profiles being equal to the difference between the open-circuit potentials and the non-equilibrium potentials for the plots of FIGS. 3 and 4), and FIGS. 5B and 5C which are the corresponding plots for the overpotential profiles of the positive and negative electrodes of the reference battery;

FIG. 6 is an illustration of a full-cell with reference electrode that may be used in an embodiment of the invention to obtain for the reference battery the open-circuit potentials in FIG. 3 and the non-equilibrium potentials in FIG. 4;

FIG. 7 illustrates a method for creating the reference overpotential fraction representation using the full-cell illustrated in FIG. 6;

FIG. 8 illustrates a reference overpotential fraction representation produced for both a positive (FIG. 8A) and negative (FIG. 8B) electrode at two different C-rates for the reference battery;

FIG. 9 illustrates a method for the estimation of individual electrode potentials using a reference overpotential fraction representation exemplified in FIG. 8.

FIG. 10 is a functional block diagram illustrating a battery control technique according to an embodiment of the invention incorporating a battery State Estimator for determining the electrode potential in real time;

FIG. 11 is a schematic illustration of how electrode potential set points may be set for each of the positive and negative electrodes to define operating and non-operating regions;

FIG. 12 is a schematic diagram showing a control process for implementing the user defined set points in a controlled charging or discharging process.

FIG. 13a to 13c illustrate an example of positive electrode potential controlled charging, compared with a known constant-current constant-voltage charging technique illustrated in FIGS. 13d to 13f.

FIG. 14a illustrates the charging current profile in an example of electrode-controlled charging, with both the positive electrode potential setpoint and the negative electrode potential setpoints are effective; FIGS. 14b and 14c show the variations in the positive electrode potential and the cell potential, and the negative electrode potential during the process;

FIG. 15 illustrates an example of electrode-controlled discharging, in a scheme to minimise electrode-related degradation and maximise discharge energy; and

FIG. 16 illustrates an example in which the positive electrode potential serves as a state-of-health indicator.

### DETAILED DESCRIPTION OF EXAMPLE EMBODIMENTS

An intelligent battery management system and method will now be described in more detail with reference to the Figures.

Examples are provided illustrating use of the battery management system for control of the charging current, and/or charging/discharging duration. Current control directly affects a battery's state-of-health, as the manner in which current is provided to or withdrawn from a battery affects the capability of the battery to continue to meet the demands made of it. The difficulty with prior art systems is that it is often not apparent what maximum current level can be supplied to or withdrawn from a battery, or for what duration a current can be supplied to or withdrawn from a battery, while avoiding degradation of the battery's state-of-health.

The battery management system discussed below addresses this by estimating one or both of the electrode potentials of the battery connected to the management system.

These electrode potentials can then be used as process values in a control system alongside set-points whose values are chosen to lower the degradation experienced by the battery.

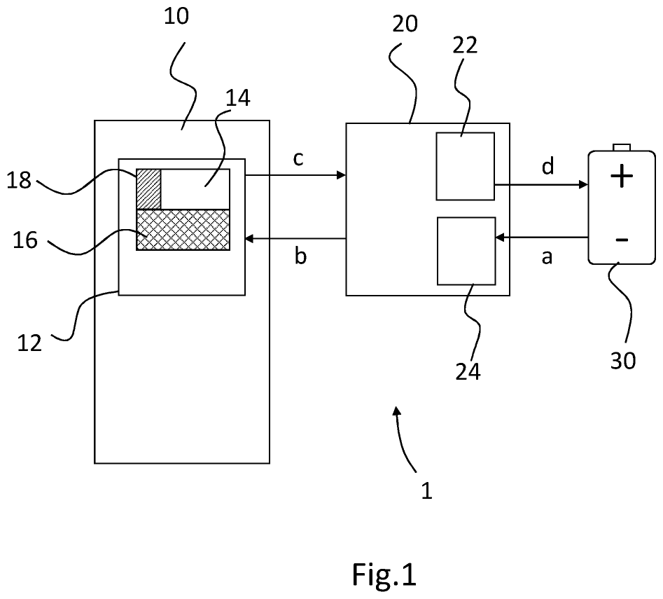

FIG. 1 illustrates an example battery management system 1 according to an example embodiment of the invention. The battery management system 1 comprises a battery management controller 10, and a battery charger/diagnostic unit 20 for connection to a battery 30. The battery charger/diagnostic unit 20 comprises charging/discharging terminals 22 for delivering a current to the battery 30, as well as one or more sensors 24 for determining one or more operational parameters indicating the state of the battery 30. These parameters may include cell potential, current measurement and/or temperature for example. In the examples that follow, the battery 30 is assumed to be a lithium ion battery.

The battery management controller 10 and the battery charger/diagnostic unit 20 may be provided separately or may be provided as a single integrated unit. Where they are provided separately, the battery management controller 10 and the battery charger/diagnostic unit 20 include appropriate input/output or transmitter/receiver terminals for wireless or wired communication. Where provided as a single integrated unit, the battery management controller 10 may be hardware installed into the battery charger/diagnostic unit 20, or may be software configured to run on a processor/controller within the battery charger/diagnostic unit 20. Although the battery charger/diagnostic unit is shown as a single combined unit, these may be provided as separate units. Further, FIG. 1 is intended to include configurations where only one of a battery diagnostic function or a battery charging/discharging function is provided.

The battery management controller 10 may be embodied in hardware or software and/or as a combination of both. Examples include software installed on an integrated circuit or dedicated chip, provided in hardware form and with or without supporting circuitry such as a printed circuit board. The battery management controller 10 may also be provided in software form as one or more control algorithms for separate delivery or download into another dedicated system. The control algorithms may be embodied by any suitable form of software controller such as a bang-bang (on/off) controller, a proportional-integral-derivative controller, or any variation thereof containing some combination of proportional/integral/derivative elements, and a model predictive controller.

In FIG. 1, the battery management controller 10 illustrated comprises a processor and connected memory 12 on which one or more control programs, software instances or algorithms are stored for execution. The control software may comprise one or more dedicated modules or layers, including an application layer 14 in which battery control algorithms reside, safety layer software 16 which ensures the safe operation of the battery, and proprietary software module 18 for predicting the battery electrode potentials of the connected battery 30 according to the technique described below. The software modules and layers 14, 16 and 18 are illustrated in FIG. 1 purely by way of example to better understand the operation of the invention, and it will be understood that other logical arrangements and implementations of the software are possible.

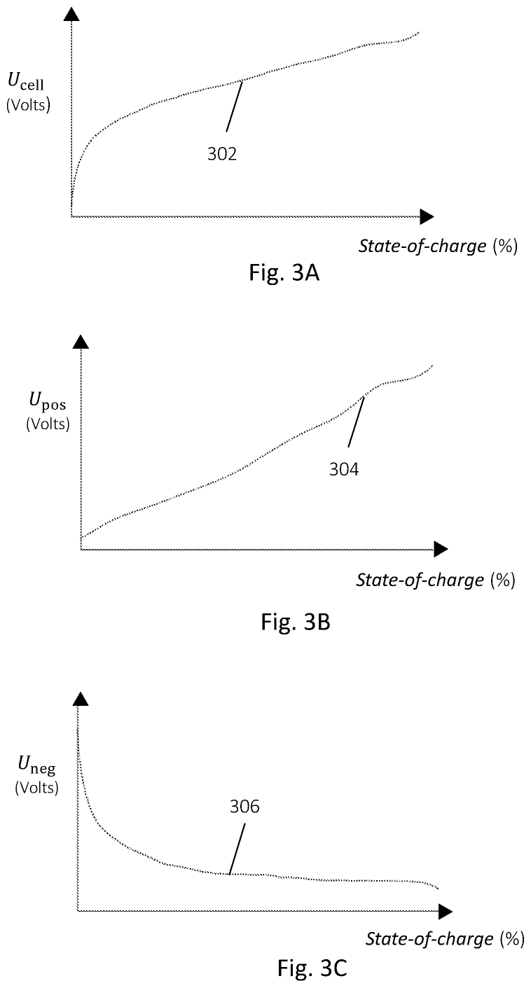

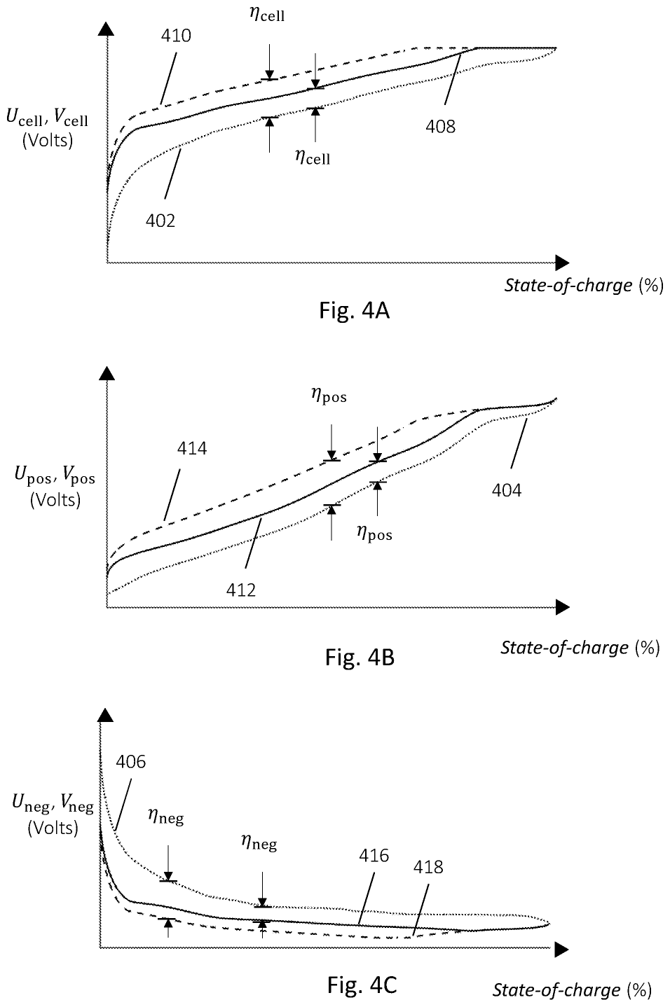

In an example operation of FIG. 1, cell potential, temperature and current measurements are obtained from the battery 30 by one or more sensors 24 (information flow a), and are transmitted (information flow b) to the battery management controller 10. These measurements are then used by the software module 18 to estimate the real time or instantaneous non-equilibrium negative and/or positive electrode potential of the battery 30, for use as the process values in a battery charging current control process implemented by modules 14 and 16. The operation of software module 18 will be described in more detail with reference to FIGS. 3 to 10. Accordingly, the software modules 14 and 16 of battery management controller 10 determine a charging set point or target and provide this (information flow c) to the battery charger/diagnostic unit 20. The battery charger/diagnostic unit 20 subsequently provides (information flow d) a charging current to connected battery 30.

The charging current is controlled in real time based on the measured parameters of the battery, in order to minimise long-term battery degradation (by avoiding lithium deposition for example in the case of a lithium ion intercalation battery), and enhance performance, such as providing a high charging current to minimise charging time, or a large operating voltage window to maximise usable energy. In other embodiments, and where appropriate, short charging times may be avoided to maintain battery health. As noted above a battery's state-of-health may be understood in terms of changes in the battery's resistance, and capacity and other factors.

In FIG. 1, software and hardware modules are discussed and illustrated. In embodiments, it will be appreciated that the software modules discussed herein may be embodied as a machine-readable medium, a computer-readable medium, or as a computer readable storage medium, and that such media may refer to any medium providing data, computer or machine instructions that cause a machine to operate in the manner described. Such media may be physical and tangible non-volatile, non-transitory storage media like floppy disks, flexible disks, hard disk, magnetic tape, CD-ROMs optical or magnetic disks, solid state storage devices, memory chips or cartridges, embodying RAM, PROM, EPROM FLASH-EPROM. This list is purely for illustration and is not intended to be exhaustive.

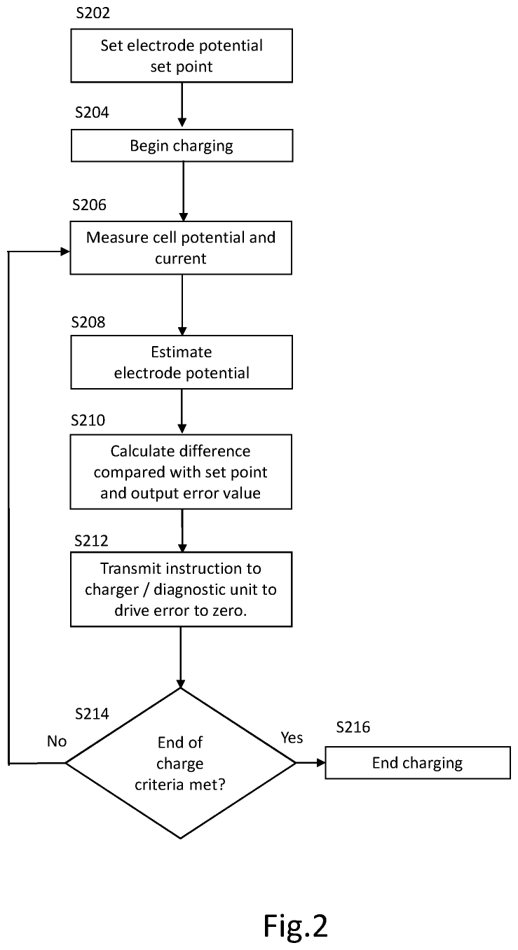

FIG. 2 illustrates an example battery charging application using the battery management system 1 of FIG. 1. The battery charging method begins in step S202 with the determination of a control set point by the battery management controller 10. The control set point is based on a physically meaningful value of electrical potential selected for the battery 30, such that by maintaining the process value at that set point value, or at a fixed distance from it, battery degradation processes are minimised.

As will be discussed later, the control set points are one or more of the non-equilibrium potentials on the negative and positive electrodes V_{neg} and Vₚₒₛ of the battery under consideration, that is the battery connected to the battery management system. This means that charging/discharging can be carried out safely, because the charger/diagnostic unit 20 is able to apply a charging/discharging current to the battery terminals based on an accurate estimate of one or both of the electrode potentials where the current is applied, rather than a general measurement of the cell potential, from which the electrode potentials cannot be understood.

To determine V_{neg} and Vₚₒₛ, the battery management method and system takes advantage of the fact that it is relatively easy to obtain the cell overpotential η_{cell} because values for the cell potential V_{cell} and cell open-circuit potential U_{cell} are easy to obtain. From an understanding of how the cell overpotential η_{cell} is made up of the overpotentials at the respective electrodes ηₚₒₛ and η_{neg}, the subtraction is simple with respect to the cell open-circuit potential data (U_{cell}) available in memory, and from the cell overpotential η_{cell} the values of V_{neg} and Vₚₒₛ can be calculated.

Using the cell overpotential η_{cell} in this way to determine the electrode potentials means that the battery management system and method exhibits a good degree of automatic adaptivity to battery ageing and battery degradation. This is because the cell overpotential η_{cell} tends to increase with battery age for a variety of reasons including for example the growth of interphase layers such as the solid-electrolyte interphase, meaning the calculated overpotential at the electrode ηₚₒₛ and η_{neg} is increased accordingly.

The result is that control decisions, such as the control of the magnitude and/or duration of current to/from the battery may automatically become more conservative as the battery degrades. This has the positive effect of prolonging battery lifetime and maintaining on average a higher degree of battery health for longer.

In FIG. 1, and assuming that the battery 30 is a lithium ion battery, a negative electrode potential set point of 0.1 Volts with respect to the reference potential of metallic lithium may be chosen. This value is based on a physically meaningful value of 0.0 Volts, above which degradation by lithium deposition is minimised, summed with a safety margin of 0.1 Volts. Where battery 30 employs a different battery technology to lithium ion, a different control set point may be appropriate. In this example embodiment, the negative electrode potential set point is determined by application and safety layer software modules 14 and 16 of the battery management controller 10 for example, based on a battery technology type input by the user, or determined by the battery management system 1 based on initial measurements when battery 30 is connected.

In step S204, and based on the determined set point, the battery management controller 10 instructs the battery charger/diagnostic unit 20 to begin applying an initial charge to the battery. The initial charge can be a pre-set level considered to be safe, such as 1C for example. Alternatively, the initial charge can be a pre-calculated level that has been estimated to produce a desirable initial relationship between the instantaneous value of negative or positive electrode potential (estimated as a process value in the charging process and based on an initial measurement of cell potential, current and/or temperature in set) and the target or set point for the negative or positive electrode potential.

The selection of the initial set point in step S202 and the determination of the initial charge in step S204 will not be described in detail in this application, which is concerned with the estimate of the individual electrode potentials and the use of this in a battery management method. A number of techniques for determining the set point and initial charging current are known to the skilled person, and need not be described further.

In step S206, the cell potential and the applied current at that moment are measured by the battery charger/diagnostic unit 20 and their values provided to the battery management controller 10. The cell temperature may additionally be measured and provided in this step, whether required for safety monitoring, or as an index to obtain temperature related parameters (e.g. variations in the overpotential fraction or open-circuit potential). These measured quantities may additionally benefit from some degree of estimation or filtering to enhance their usefulness and/or accuracy.

In step 208, the measured quantities are used as inputs by the battery management controller 10 to determine an estimate of the negative and/or positive electrode potential (the process value(s)) at the instant in time. The method for doing this is discussed below in more detail in connection with FIGS. 3 to 10.

In step S210, the battery management controller 10 calculates the difference between the process value(s) and the set point value(s) received in step S202, and based on the difference, determines an error value.

In subsequent step S212, the battery management controller 10 determines, based on the error value, an appropriate control instruction for the battery charger/diagnostic unit 20 charging process, for example how the charging current target should be adjusted, to drive the error value to zero in the next instant, and transmits this to the battery charger/diagnostic unit 20. This is a target which defines the maximum permissible charging current that should be provided for the battery 30 taking the present battery state into account. There may be reasons why the charger provides a current to the battery which is less than the target being broadcast from the invention, such as an over-riding safety function interfering.

In step S214, the battery management controller 10 determines whether the end-of-charge criteria are met in order that the charging process ends safely. Criteria for ending the charging process may be one or more of a cell potential target such as 4.2 Volts having been reached, a state-of-charge target having been reached, such as 100% state-of-charge, a temperature target having been reached, such as the battery reaching 50 degrees Celsius, and/or a charging time target having been reached, such as 30 minutes having elapsed. It will be appreciated that this is a non-exhaustive list, and that other criteria may apply.

If the end-of charge criteria are determined to have been met in step S214 (Yes), then the charging process ends in step S216. While ever the end-of-charging criteria are deemed not met, the charging process is ongoing, and the method returns to step S206 in which the battery management controller 10 measures cell potential and current, and in the closed-loop feedback process of steps S208 to S214, determines a process value indicating the potential of the negative electrode, compares the process value against the set point, determine whether and by how much the charging current target being transmitted from the battery management controller 10 to the battery charging/diagnostic unit 20 should be adjusted, and transmit this to the battery charger/diagnostic unit 20. Charging continues at this revised current level at the next instant and the process repeats until an end-of-charge state, all the while producing a dynamic current in response to an estimate of the negative or positive electrode potential vs. a set point. Consequently, when the charger/diagnostic unit 20 provides the target current to the battery, the input current profile will typically vary with time in a manner that has minimised (or best sought to minimise) the error.

As noted above, the charging method of FIG. 2 relies on estimating the negative electrode potential of the connected battery 30 and using this as a process value in the method to control the applied current. The method of estimating the negative electrode potential will now be described in more detail with reference to FIGS. 3 to 10.

### Background and Discussion of Overpotentials

First, and with reference to FIGS. 3 to 5, the concepts of open-circuit potential, polarisation and overpotentials will be discussed.

By way of introduction, FIG. 3 illustrates the open-circuit potentials for a cell as a function of the battery state-of-charge. The open-circuit potential is the electric potential under equilibrium, that is the electric potential when no current is passing through the battery, of either a battery or a material such as the positive or negative electrode. FIG. 3 illustrates the open-circuit potential (FIG. 3A), the positive electrode (FIG. 3B) and the negative electrode (FIG. 3C) against the state-of charge (%) of the battery. Each of the respective potentials, 302, 304 and 306 will be understood to be functions of both the state-of-charge, and of other factors such as the battery temperature and the battery's degradation state (i.e. the battery's health). For the purposes of illustration, the additional dependencies of the open-circuit potential on temperature and other factors, as well as additional properties such as hysteresis, are not illustrated but will be understood to apply.

The relationship between cell open-circuit potential U_{cell} and the open-circuit potentials of the positive Uₚₒₛ and negative U_{neg} electrodes is given by Equation 1 as:

$${U}_{cell} = {U}_{p o s} - {U}_{n e g} \qquad Equation 1$$

Referring to FIG. 3A, profile 302 illustrated in FIG. 3A is therefore the difference between profiles 304 and 306 in FIGS. 3B and 3C.

When a charge or discharge current is applied to a cell polarisation occurs, leading to an offset of the potentials from their open-circuit potentials. Polarisation is the term given to the departure of a potential from the open-circuit potential, arising from one or more sources (ohmic “IR”, activation and concentration). The resulting potentials may be considered to be non-equilibrium potentials represented by V. As before, the cell potential V_{cell} is the difference between the electrode potentials Vₚₒₛ and V_{neg}:

$${V}_{cell} = {V}_{p o s} - {V}_{n e g} \qquad Equation 2$$

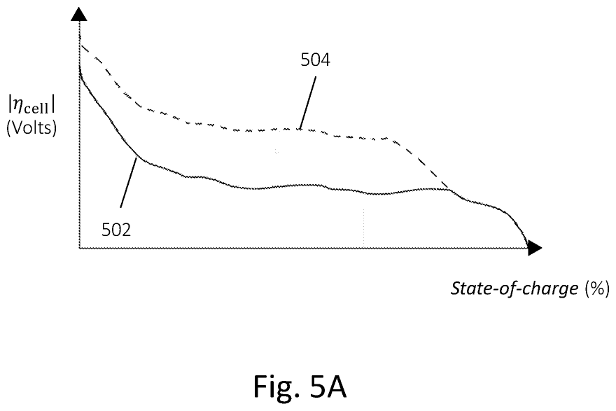

FIG. 4 shows how, when the battery is in a non-equilibrium condition, polarisation results in an offset of the potentials from their open-circuit values. Dotted lines 402, 404 and 406 in FIG. 4 illustrate the open-circuit potentials U_{cell}, Uₚₒₛ and U_{neg} illustrated in FIG. 3, while the bold lines 408, 412 and 416, and the dashed lines 410, 414, and 418 indicate the non-equilibrium potentials V_{cell}, Vₚₒₛ and V_{neg} at a low charging current and a high charging current respectively (different C rates).

The magnitude of the polarisation is referred to as the overpotential η_{cell}, ηₚₒₛ and η_{neg} and is illustrated in FIGS. 4A, 4B and 4C by the deviation away from the dotted line curve for both the bold and dashed line charging scenarios. Mathematically, the overpotential is defined as:

$${η}_{cell} = {V}_{cell} - {U}_{cell} \qquad Equation 3$$

$${η}_{p o s} = {V}_{p o s} - {U}_{p o s} \qquad Equation 4$$

$${η}_{n e g} = {V}_{n e g} - {U}_{n e g} \qquad Equation 5$$

By definition, during cell charging, η_{cell} and ηₚₒₛ are positive quantities while η_{neg} is a negative quantity. Although FIG. 4 depicts behaviour arising from the application of a charging current to the battery, this could alternatively be illustrated under the application of a discharging current, in which case the potentials would instead, relative to the open-circuit potential, be lower for the cell, lower for the positive electrode, and greater for the negative electrode. The three quantities adopt the opposite signs during cell discharging.

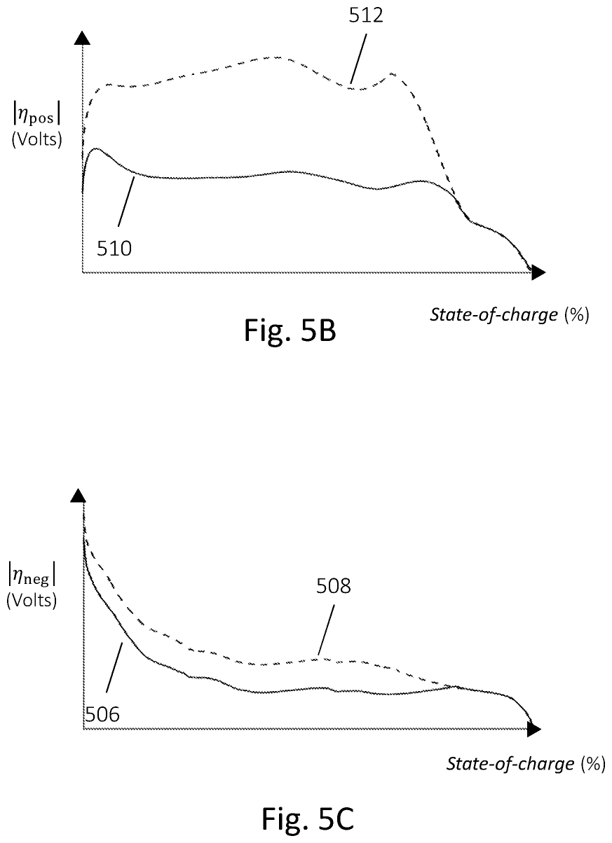

FIGS. 5A, 5B and 5C shows for each of FIGS. 4A, 4B and 4C, the corresponding magnitude of the overpotentials expressed as a function of the state-of-charge. It will be appreciated that these are non-linear functions, varying in dependence on a number of parameters.

In FIG. 5B, curve 510 is the absolute positive electrode overpotential ηₚₒₛ with a relatively low applied charging current, while 512 is the absolute positive electrode overpotential ηₚₒₛ with a relatively high applied charging current. Similarly, in FIG. 5C, plot 508 is the absolute negative electrode overpotential η_{neg} with a relatively low applied charging current, and 506 is the absolute negative electrode overpotential η_{neg} with a relatively high applied charging current. As can be seen in these figures, the overpotentials are not linear, and they can vary significantly with the state-of-charge of the battery.

The profiles illustrated in FIGS. 3, 4 and 5 were generated using a commercially-available lithium-ion intercalation style rechargeable battery with a graphitic negative electrode and a composite nickel-cobalt metal oxide positive electrode, at a battery temperature of 25 degrees Celsius.

In this case, the U_{cell} in profile 302 of FIG. 3A may adopt values ranging from 2.5 V at a 0% state-of-charge to 4.2 V at a 100% state-of-charge. Uₚₒₛ in profile 304 of FIG. 3B may adopt values ranging from 3.54 V at a 0% state-of-charge to 4.24 V at 100% state-of-charge. U_{neg} in profile 306 of FIG. 3C may adopt values ranging from 1.04 V at 0% state-of-charge to 0.04 V at 100% state-of-charge.

In FIG. 4A, plot 402 illustrates the same cell open-circuit potential U_{cell} shown previously as 302, having an example value of 3.73 V at 50% SOC, while plot 408 illustrates the cell potential V_{cell} with a relatively low applied charging current of 1 C (4 amperes), having an example value of 3.90 V at 50% SOC, and plot 410 illustrates the cell potential V_{cell} with a relatively high applied charging current of 2 C (8 amperes), having an example value of 4.04 V at 50% SOC.

Similarly, in FIG. 4B, curve 404 illustrates the same positive electrode open-circuit potential Uₚₒₛ shown previously as 304, having an example value of 3.86 V at 50% SOC. Curve 412 is the positive electrode potential Vₚₒₛ with a relatively low applied charging current of 1 C, having an example value of 3.94 V at 50% SOC, and 414 is the positive electrode potential Vₚₒₛ with a relatively high applied charging current of 2 C, having an example value of 4.02 V at 50% SOC.

Lastly, in FIG. 4C, curve 406 is the same negative electrode open-circuit potential U_{neg} illustrated previously as 306, having an example value of 0.13 V at 50% SOC. Curve 416 is the negative electrode potential V_{neg} with a relatively low applied charging current of 1 C, having an example value of 0.04 V at 50% SOC, while curve 418 is the negative electrode potential V_{neg} with a relatively high applied charging current of 2 C, having an example value of −0.02 V at 50% SOC.

In FIG. 5A, 5B and 5C prior to the absolute values being taken, typical values of η_{cell}, ηₚₒₛ and η_{neg} at 50% state-of-charge would be 0.17 V, 0.08 V and −0.09 V, respectively, for the same relatively low applied charging current.

### The Method

As noted above, the battery management system and method relies on the ability to attribute a fraction of the overall cell overpotential η_{cell} (which can be easily measured for a commercial available cell using the apparatus of FIG. 1) to each of the positive and negative electrodes, thus obtaining an estimate of the overpotentials ηₚₒₛ and η_{neg} at each of the respective electrodes. Mathematically, the overpotentials can be expressed as a function of the cell overpotential η_{cell} as follows:

$${η}_{p o s} = {η}_{cell} \times {η}_{f , pos} \qquad Equation 6$$

$${η}_{n e g} = {η}_{cell} \times {η}_{f , neg} \qquad Equation 7$$

where η_{f,pos} and η_{f,neg} are the fractions of the total cell overpotential η_{cell} attributed to the positive and negative electrode respectively. Since the fraction of cell overpotential which should be attributed to each electrode is non-constant and instead varies with state-of-charge, and with other factors including the applied current level, these fractional values are stored as look-up tables or as mathematical functions in computer memory for a reference battery. These are referred to as reference overpotential fraction representations (or overpotential fraction maps) and they enable the estimation of electrode potentials under a wide range of battery usage.

The operation parameters of a new battery connected to the battery management system 1, specifically the negative and/or positive electrode values of the connected battery, can then be deduced from simple measurements of quantities like the battery terminal potential and a measurement or estimation of the battery's state-of-charge, and comparison with the overpotential fraction maps stored in memory for the reference battery. This requires that the reference battery used to generate the map be a good approximation for any battery later connected to the battery management system. Necessarily, the battery management system may therefore store maps and/or tables for different types of battery technology, such that if a lithium ion battery is connected to the battery management system, an overpotential fraction map is available in memory to consult.

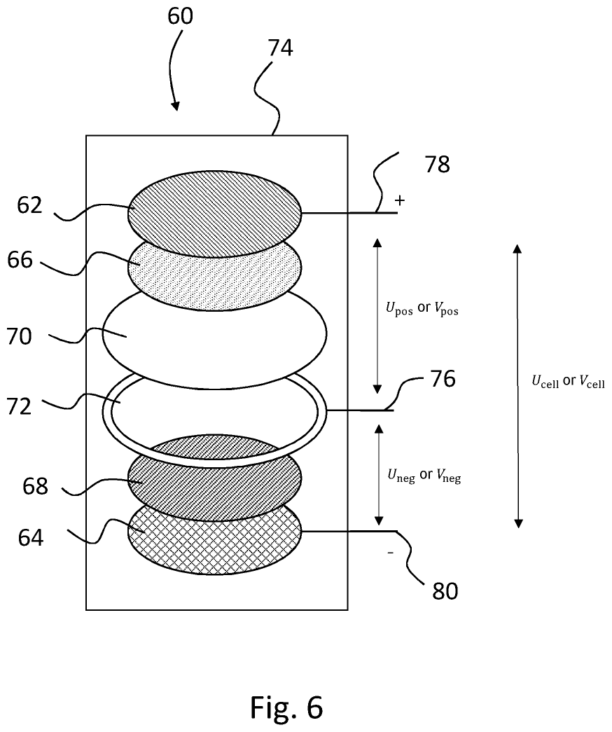

An apparatus and method for determining the overpotential fraction maps will now be described, in connection with FIGS. 6, 7 and 8.

FIG. 6 is a diagram showing an experimental full-cell with reference electrode, which allows the open-circuit potential and overpotential data for the cell, and for the positive and negative electrodes to be determined for a test or reference battery, for any number of different charging scenarios and battery parameters. For each battery type or model to be used with the battery management controller 10 it will be necessary to analyse a characteristic test cell and obtain the data and save this in memory as one or more look-up tables or functions for the purposes of the calculation to be used by the battery management controller.

It is sufficient for satisfactory operation of the battery management controller, if the data sets are determined for each type of battery, assuming new battery materials in which no use dependent degradation has yet occurred, for at least one value of charging current. Preferably, data sets for respective battery types involving different charging currents, different battery temperatures, and/or different battery states of health may also be generated. If these additional data sets are not generated experimentally by direct measurement using the experimental system of FIG. 6, then they may be calculated with reasonable accuracy by interpolation or calculation based on the data determined for a new battery at a single temperature.

The data shown in FIG. 3 for example may be generated by measurement using the apparatus of FIG. 6 for a reference battery, and be available in memory as one or more open-circuit potential representations for use in the battery management method. Each of the respective potentials, 302, 304 and 306 will be understood to be functions of both the state-of-charge, and of other factors such as the battery temperature and the battery's degradation state (i.e. the battery's health). For the purposes of illustration here the additional dependencies of the open-circuit potential on temperature and other factors, as well as additional properties such as hysteresis, are not illustrated but will be understood to apply. In embodiments, the data in FIGS. 4 and 5 may also be generated and stored.

Referring now to FIG. 6, an experimental full-cell 60 with a reference electrode is illustrated. Preferably, this is constructed from new electrode materials which correspond to the battery technology of the commercial batteries that will be used with the battery management controller 10. In this application, lithium ion battery technology is assumed to be a preferred battery type, and FIG. 6 therefore illustrates an experimental measurement cell corresponding to a lithium ion battery technology.

The experimental full-cell 60 comprises positive electrode current collector 62, which may be an aluminium foil, a negative electrode current collector 64, which may be a copper foil, a sheet of positive electrode material 66, a sheet of the negative electrode material 68, and a separator 70 which may be fresh or harvested from the existing cell. This may for example be a polymeric or glass-fibre material with a thickness of approximately of 20 micrometres. The experimental full-cell 60 further comprises a reference electrode 72, which may be lithium metal, and which is not intended to actively participate in the electrochemical reactions of the full-cell. It is this reference electrode which enables the measurement of the individual (i.e. positive and negative) electrode potentials in an experimental setting, as illustrated in the figures above.

Components 66 to 70 are wetted with an electrolyte, which may be a salt such as lithium hexafluorophosphate (LiPF6) acting as a solute, dissolved in a solvent mixture such as a combination of ethylene carbonate, diethyl carbonate and dimethyl carbonate. The wetted stack of components is then installed in a hermetically sealed casing 74 providing electrical connections between battery measurement equipment, and a connection point 76 for the reference electrode 72, a connection point 78 for the positive electrode's current collector 62, and a connection point 80 for the negative electrode's current collector 64. These connections permit measurement of the full-cell potential, of positive electrode potential with respect to the lithium metal reference electrode 72, and finally of the negative electrode potential with respect to the lithium metal reference electrode.

Before the experimental full-cell 60 is used to generate the reference data for the battery management system 10, formation cycling is carried out, in which the reference cell is charged and discharged, to form (or re-form) protective layers on electrode surfaces. After formation cycling, the experimental cell can be used to obtain the three open-circuit potential datasets for the cell, and the respective positive and negative electrodes.

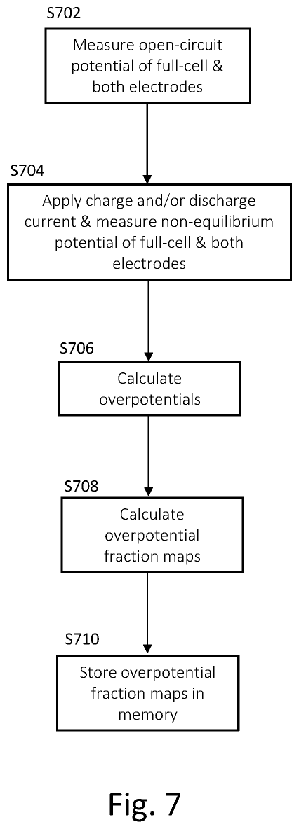

With reference to FIG. 7, a method for generating the overpotential fraction maps will now be described. Although this method applies for the generation of the overpotential fraction maps for any battery technology, it will again be described in the context of a lithium ion battery, and the open-circuit and non-equilibrium potential plots illustrated in FIG. 4.

As noted above, it is sufficient if the charging profiles are generated for a single operational temperatures. To do so, the cell may be: a) charged or discharged extremely slowly (e.g. at a C-rate of C/50) so that overpotentials are minimised and the potentials recorded are good approximations of the open-circuit potentials; b) charged or discharged between various state-of-charge levels, with the current then being removed, and the cell potentials allowed to relax and converge to the open-circuit potential at that state-of-charge; c) other method of open-circuit potential determination using charging/discharging techniques which will be known to the skilled person.

In step S702, to produce the exemplary open-circuit data sets in FIG. 3 for U_{cell}, Uₚₒₛ and U_{neg}, the reference cell illustrated in FIG. 6 was operated using a constant-current C/50 (0.08 ampere) rate charging process and a constant-current C/50 rate discharging process. The low charging/discharging current is selected to approximate an equilibrium situation in which the measured cell potential closely approximates the open-circuit potential. The resulting open-circuit potentials at each state-of-charge value were recorded, and following the respective charging and discharging process, the resulting cell potential profiles for each of the respective potential curves (U_{cell}, Uₚₒₛ and U_{neg}) were averaged or interpolated to produce plots 302, 304, and 306. Step S702 is preferably carried-out with the reference cell in a controlled-temperature environment. As noted above, a typical temperature is 25 degrees Celsius, although other temperatures may be used, corresponding to battery temperatures that might be encountered in practice, such as negative 40 degrees Celsius to positive 50 degrees Celsius.

In step S704, the non-equilibrium potentials exemplified in FIG. 4 are produced, by operating the reference cell to charge and/or discharge at higher currents than in step S702, such that the cell potential and the positive and negative electrode potentials are driven away from their open-circuit values by more than is experienced with the low currents used in step S702 previously aimed at approximating equilibrium. For example, a charging current of 4 amperes may be applied in step S704, which is 50 times greater than the 0.08 ampere current used in the approximation of open-circuit potential in step S702.

Again, the reference cell is operated at a temperature of 25 degrees Celsius for consistency with step S702, over the same state-of-charge window. The cell potential and electrode potentials are measured under the application of these currents for a charging and/or discharging process and stored. They may then be smoothed, post-processed or interpolated to generate the bold and/or dashed line plots 408, 410, 412, 414, and 416, 418 of FIG. 4.

When choosing a current level to use in step S704 it is desirable to use a level that is close to the current level likely to be encountered in commercial applications for the battery. In this way, any dependency of the overpotential fraction map obtained on the charging/discharging current can be accounted for, and matched with the likely current encountered during use in order to improve accuracy.

In step S706, the overpotential profile over the same state-of-charge window is now calculated, based on the open-circuit potentials and the non-equilibrium potentials obtained in steps S702 and S704. The overpotential η is calculated for each of the full-cell, positive electrode and negative electrode according to the equations provided earlier, namely:

$${η}_{cell} = {V}_{cell} - {U}_{cell} \qquad Equation 3$$

$${η}_{p o s} = {V}_{p o s} - {U}_{p o s} \qquad Equation 4$$

$${η}_{n e g} = {V}_{n e g} - {U}_{n e g} \qquad Equation 5$$

FIGS. 5A, 5B and 5C discussed above illustrate the overpotential profiles calculated from the data shown in FIGS. 3 and 4.

In step S708, overpotential fraction maps η_{f,pos} and η_{f,neg} for each of the positive and negative electrodes are produced, wherein the overpotential at each electrode is obtained as a fraction of the full-cell overpotential under that same circumstance. Since each of η_{cell} ηₚₒₛ and η_{neg} are known, and based on Equations 6 and 7 above, the fraction maps can be calculated for each respective value of state-of-charge across the state-of-charge window according to the following equations:

$${η}_{f , pos} = \frac{{η}_{p o s}}{{η}_{cell}} \qquad Equation 8$$

$${η}_{f , neg} = \frac{{η}_{n e g}}{{η}_{cell}} \qquad Equation 9$$

In other words, the overpotential fraction maps can be understood to be profiles which at any given state-of-charge value, represent the fractional amount of the total cell overpotential η_{cell} that is attributable to the potential at the positive electrode and the negative electrode.

For any given state-of-charge value, the positive electrode overpotential fraction η_{f,pos} is the ratio of the overpotential ηₚₒₛ occurring at the positive electrode to the cell overpotential η_{cell}. The negative electrode overpotential fraction η_{f,neg} is the ratio of overpotential η_{neg} occurring at the negative electrode to the cell overpotential η_{cell}. Expressed mathematically, the overpotential fraction maps behave as:

$$1 > {η}_{f , pos} > 0$$

$$1 > {η}_{f , neg} > 0$$

$${η}_{f , neg} + {η}_{f , pos} \approx 1$$

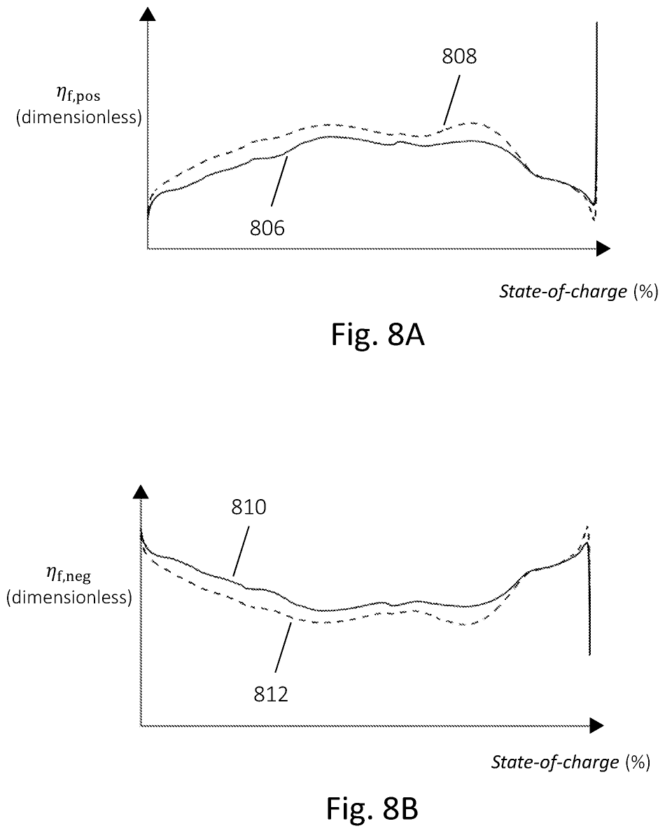

The overpotential fraction maps are illustrated in FIGS. 8A and 8B. In FIG. 8A, plot 806 is a positive electrode overpotential fraction map for a relatively low current, while plot 808 is a positive electrode overpotential fraction map for a relatively high current. In FIG. 8B, plot 810 is a negative electrode overpotential fraction map for a relatively low current, while 812 is a negative electrode overpotential fraction map for a relatively high current. Although FIGS. 8A and 8B give each map for two different exemplary charging currents, and each map is shown only for a single temperature and state-of-health, in embodiments maps be generated to include these additional dependencies.

In FIGS. 8A and 8B, typical values for η_{f,pos} and η_{f,neg} at 50% state-of-charge and the same relatively low applied current would be 0.47 and 0.53, respectively, and the overpotential fraction maps exemplified are based on underlying open-circuit potential and non-equilibrium potential data obtained at 25 degrees Celsius. Although, in the example shown for FIG. 8, there exists a trend for the positive electrode overpotential fraction to increase at the expense of the negative electrode's overpotential fraction as the current is increased, this behaviour may differ with different batteries and different materials.

In step S710, the overpotential fraction maps are stored in memory and are then available for use by the battery management controller 10. Owing to behaviour given earlier whereby η_{f,neg}+η_{f,pos}≈1, it is alternatively possible to store only the overpotential fraction for one electrode in memory and to calculate the overpotential fraction for the second electrode as-needed by subtracting the overpotential fraction in memory from unity. In this way, memory requirements for the invention or for the battery management controller 10 may be reduced.

It is not necessary to repeat steps S704 to S710 once the maps for a particular battery and temperature have been completed. However, doing so and having multiple overpotential fraction maps available across a range of currents (and temperatures) can improve the accuracy of electrode potential estimation in the subsequent battery management method.

In practice, when higher charge/discharge currents are applied to the reference electrode cell in step S704, the resulting polarisation can be large and can force an earlier termination of the charge/discharge process when the cell potential reaches a limiting value, such as an upper cut off of 4.2 Volts in the case of charging. This earlier cut-off may make it challenging to obtain cell and electrode potential data in the high (charging scenario) and low (discharging scenario) state-of-charge range. The quantity of unobtainable data typically increases with increasing rates (notwithstanding the ability of temperature to reduce the polarisation). A post-processing step where unobtained data values are obtained by imputation or similar process may be used to alleviate the issue.

The method for determining the overpotential fraction maps illustrated in connection with FIGS. 6 to 8 has been based on discussion of a lithium-ion battery. However, the method is not restricted to lithium-ion batteries and it can also be used with a wide range of batteries and electrochemical systems. In the case of different battery technologies, the process of FIG. 7 would need to be completed for each respective battery technology.

In addition to the reference electrode full cell such as that exemplified in FIG. 6, the overpotential fraction maps of FIG. 8 may be produced instead by using a pair of half-cells. In such a case, the first half-cell consists of the following elements: one electrode which would ordinarily be the positive electrode in a full-cell, and a counter-electrode made of a reference material such as lithium metal. The second half-cell consists of the following elements: one electrode which would ordinarily be the negative electrode in a full-cell, and a counter-electrode made of a reference material such as lithium metal.

Alternately, the overpotential faction maps may be produced by operating a battery model, e.g. via computer simulation, or by insertion of sensors or reference electrodes into cells, which may be capable of outputting the electrode potential data in a similar fashion to that available from the above-described experiments with a full-cell or pair of half-cells. Compared with the experimental approach, producing the overpotential fraction maps using a model can reduce or eliminate the need for laboratory work and provide a more computer based and potentially an even cheaper, faster method of obtaining the advantages of the invention.

### General Implementation

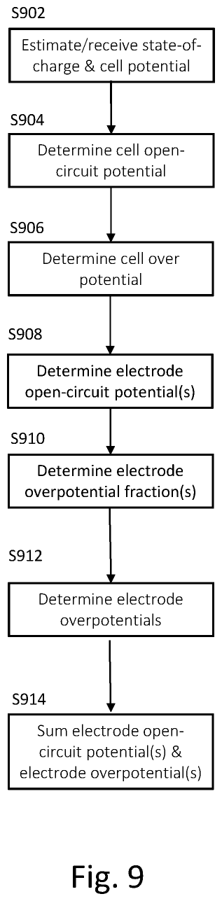

Referring now to FIG. 9, a method of estimating the negative electrode potential required for step S208 of the battery control method of FIG. 2 will now be described.

In step 902, the battery management controller 10 receives from the charger/diagnostic unit 20 a measurement of the battery potential of the connected battery, and either receives or determines a value for the state-of-charge of the battery.

The state-of-charge of the battery is not a directly measurable quantity, and many methods exist for its estimation. A typical example is “coulomb-counting”, whereby current is measured with a sensing device such as a shunt resistor, and charge throughput is recorded and used to estimate state-of-charge. Any suitable method may be used by the battery management controller 10, including provision of the state-of-charge estimate from another element of software based on the measured battery potential, or by using a look-up table stored in memory. A measured or estimated battery temperature may be an additional input here, particularly if it is required for acquiring or indexing data stored in memory, such as open-circuit potentials or overpotential fraction maps generated for specific temperatures.

In step S904, the cell open-circuit potential U_{cell} of the connected battery at the state-of-charge estimated or determined in step S902 is obtained from the appropriate open-circuit potential representation available in memory for U_{cell} (see FIG. 3A) by indexing with state-of-charge. The data stored for the reference battery is used as a look-up using the state-of-charge determined for the connected battery as the look-up key. This assumes that the connected battery behaves identically to the reference battery for which data is stored. In practice, this approximation has been found to be satisfactory. In embodiments, the lookup table may be replaced or implemented in part by a mathematical function representing the U_{cell} profile.

In step S906, a value for the battery overpotential is calculated by subtracting the battery open-circuit potential calculated in step S904, from the battery potential measured in step S902.

In step S908, the open-circuit electrode potentials U_{neg} and/or Uₚₒₛ of the connected battery at the state-of-charge estimated or determined in step S902 is obtained from the appropriate representation stored in memory for U_{neg} and Uₚₒₛ (see FIGS. 3B and 3C) by indexing with the determined state-of-charge. In embodiments, the representation may be a look-up table or implemented in part by a mathematical function representing the U_{neg} and Uₚₒₛ profiles.

In step S910, the overpotential fractions η_{f,pos} and/or η_{f,neg} of the connected battery at the determined state-of-charge and temperature is then obtained from the appropriate overpotential fraction representation available in memory (See FIGS. 8A and 8B) by indexing with state-of-charge. Again, in embodiments this may be achieved using a look-up table or implemented in part by a mathematical function representing the η_{f,pos} and η_{f,neg} profiles.

In step S912, and knowing the cell overpotential from step S906 and the electrode overpotential fractions η_{f,pos} and/or η_{f,neg} from step S910, the electrode overpotential ηₚₒₛ and/or η_{neg} is now determined for one or both of the electrodes according to:

$${η}_{p o s} = {η}_{cell} \times {η}_{f , pos} \qquad Equation 6$$

$${η}_{n e g} = {η}_{cell} \times {η}_{f , neg} \qquad Equation 7$$

Finally, in step S914, and based on the electrode overpotentials ηₚₒₛ and η_{neg} calculated in step S912 and the electrode open-circuit potentials U_{neg} and/or Uₚₒₛ calculated in step S908, the non-equilibrium electrode potentials V_{neg} and Vₚₒₛ for the negative and/or positive electrodes are now calculated, according to:

$${V}_{p o s} = {U}_{p o s} + {η}_{p o s} \qquad Equation 10$$

$${V}_{n e g} = {U}_{n e g} + {η}_{n e g} \qquad Equation 11$$

In step S914, non-absolute values of all quantities are used in calculation such that during battery charging:

$${η}_{p o s} > 0 so that {V}_{p o s} > {U}_{p o s} , and$$

$${η}_{n e g} < 0 so that {V}_{n e g} < {U}_{n e g}$$

And during battery discharging:

$${η}_{p o s} < 0 so that {V}_{p o s} < {U}_{p o s}$$

$${η}_{n e g} > 0 so that {V}_{n e g} > {U}_{n e g}$$

The positive and negative electrode potentials can thus be calculated for any battery connected to the battery management controller based merely on a measurement of the battery cell potential, and an estimation of the battery state-of charge. Optionally, additional parameters may be measured or estimated to improve accuracy. Once Vₚₒₛ and V_{neg} have been calculated according to FIG. 9, the method of FIG. 2 can continue at step S210 accordingly.

It will be appreciated that although the steps of FIG. 9 have been presented in a particular order, this is merely for ease of understanding, and not intended to limit the invention. Steps S908 to determine the electrode open-circuit potential for example could occur at any stage of the method, provided the electrode open-circuit potentials are ready for use in step S914.

In all cases above, another index may be used in place of state-of-charge. Equally, state-of-charge may not be the only index used, and temperature, current, or others may be additionally used. That is, lookup tables may be multi-dimensional and/or functions may contain multiple variables.

### Adapting to Battery Degradation

As electrochemical systems are used through their life, they tend to evolve and suffer from degradation leading to loss of performance and a change in their behaviour. Electrochemical behavioural changes include changes to potential profiles over the state-of-charge range, charge capacity, energy capacity and power capability.

The use of cell overpotential as a major element in the determination of electrode potential estimates means that the invention inherently exhibits a degree of adaptivity to battery degradation. This is because as a battery degrades, that degradation typically manifests as a change in the battery resistance and a change in the overpotential. By taking this into account when making electrode potential estimates, the invention is differentiated from other approaches to battery control which do not exhibit this adaptivity, such as the use of pre-determined charging current profiles defined over time or a state-of-charge window.

Nevertheless, as a result of degradation, some recorded battery parameters and maps which were initially good representations of behaviour at the beginning of a battery's life may no longer be as good later on in life. To extract more consistent, or a higher average level of performance from the invention, embodiments of the battery management control may attempt to account for this degradation by making adjustments to the parameters and/or maps using dynamic updates to the open-circuit potentials.

A slow charge or discharge (for example at a rate in the range C/10 to C/50) may be performed on a degraded battery. This may serve one or both of two purposes. Firstly, this can produce an updated battery capacity value accounting for any loss of charge capacity that has occurred through degradation. This updated battery capacity value may then be used to enhance or maintain the accuracy of the state-of-charge estimates being used as indices in the invention. Secondly, the recorded cell potential U_{cell,degraded} can be assumed to be a sufficiently close representation of the cell's open-circuit potential vs. state-of-charge in the cell's degraded state. It will be a variation of the new cell's open-circuit potential previously given in 302, FIG. 3.

The following error e may then be calculated across a common state-of-charge window, such that all four terms are vector-quantities:

$$e = {U}_{cell , degraded} - ( {U}_{p o s} - {U}_{n e g} ) \qquad Equation 12$$

Where the Uₚₒₛ−U_{neg} term provides the calculated cell's open-circuit potential U_{cell} when new, in terms of the individual electrode open-circuit potentials which were available from computer memory, having been obtained initially in S902. The error can be expected to be non-zero owing to the occurrence of degradation. That is to say that graphically, the subtraction of the negative electrode open-circuit potential profile 306 from that of the positive electrode 304 will no longer produce the latest available measurement of the cell open-circuit potential, U_{cell,degraded}.

A non-zero error indicates that the open-circuit parameters U_{cell}, Uₚₒₛ and U_{neg} would benefit from an update. The updated values may be obtained as follows:

The cell open-circuit potential U_{cell} may be replaced in available memory by U_{cell,degraded} measured on the slow charge or discharge, or some variation thereof, such as an average of that measured on the slow charge and discharge

An optimisation may be performed with the goal of adjusting Uₚₒₛ to a new vector quantity U_{pos,degraded} and of adjusting U_{neg} to a new vector quantity U_{neg,degraded} such that the magnitude of the error value e is reduced towards zero. In such a case, Uₚₒₛ is replaced in computer memory with U_{pos,degraded}, and U_{neg} is replaced by U_{neg,degraded}.

The outcome is three new datasets, one describing a new version of profile 302 in FIG. 3A having been obtained by measurement, another describing a new version of 304 having been obtained by optimisation and another describing a new version of 306 having also been obtained by optimisation.

In general the frequency of dynamic updates can be given by: opportunistic timings, with updates occurring when the application provides a window in which the updates can be carried-out without interrupting normal usage, for example, during downtime such as an electric vehicle laying idle overnight, or during charging; a schedule of fixed time periods throughout the lifetime of the battery, for example, monthly; and/or a schedule of fixed amounts of degradation, as measured by some metric or combinations of metrics, for example, every 5% loss of battery charge capacity measured at a 1 C charge rate.

The relatively low computer memory requirements of the invention make it possible to pre-load updated parameters that are obtained in advance of the first use of a battery and which are based on its expected degradation.

FIG. 6 illustrates the construction of a reference full-cell in which the electrodes were new. It is possible to reconstruct the reference full-cell using electrodes which are degraded. To do so, the existing full-cell prior to its disassembly may for example be degraded through usage, and then disassembled to harvest the electrodes.

Acquiring open-circuit potential data (702) and non-equilibrium potentials (704) using these degraded electrodes will provide open-circuit potential data (similar to FIG. 3) that more accurately represents that of the battery when it is aged (i.e. following some degree of time or usage). Moreover, producing overpotential fraction maps (708) using this data produces maps that are also more representative of the overpotential fractions of an aged battery.

The method and extent of ageing applied to the battery prior to its disassembly for electrode harvesting can be designed in an attempt to closely mimic that which is expected in the battery on which the invention will be used.

In the case of dynamic updates or pre-prepared updates, the parameters may be stored, along with diagnostic data, to provide information on the safety, health/degradation pathway throughout life and for any further use or disposal or recycling of the cell. That is, the diagnostic information obtained may be stored and used at a later date to inform further use of the battery beyond its first life.

Finally, it is possible to combine the two approaches; dynamic updates and pre-loaded updates together.

### Variations

The example implementation of the invention in FIGS. 1 and 2 is one where the invention is used to control charging current. In alternative embodiments, other similar parameters or proxies of charging current may be instead controlled, such as current density (areal or volumetric), C-rate, power (Watts), power density (areal or volumetric), E-rate (the ratio of power to battery capacity).

A further alternative exemplary application is one where the invention is used to control the duration of a charge or discharge process. In such an example the end-of-charge/discharge may be controlled by the process value(s) (electrode potential(s)) having reached, or become within a set range of, the set point(s). The set point value(s) and at which end-of-charge/discharge occurs might be chosen such that the battery is protected from excess degradation. For example, set point(s) chosen to prevent a positive electrode potential from falling “too” far, and/or negative electrode potential from rising “too” high, during a discharge process. Alternative example; set point(s) chosen to prevent positive electrode potential from rising “too” high during a charging process and/or negative electrode potential falling “too” low, and so terminating the charging process.

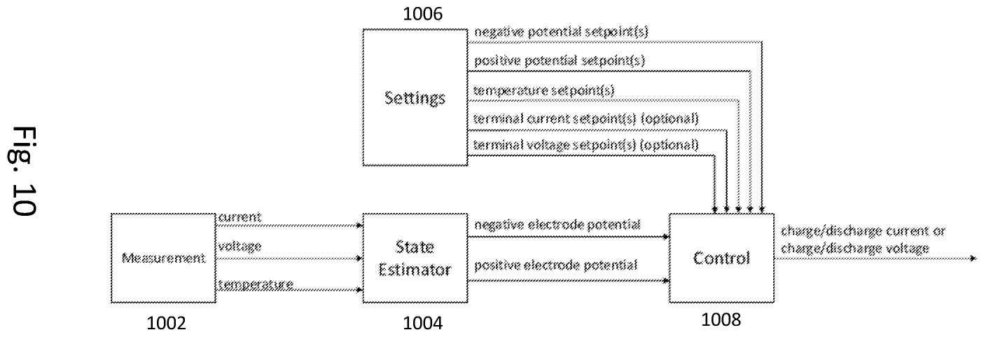

Further, the example of FIG. 2 presented a case where only one process value was used (negative and/or positive electrode potential). There may instead be one or more process value/set point pairs in use. For example negative electrode potential, positive electrode potential, or both, providing enhanced control and protection to the battery. This is discussed below in connection with FIGS. 10 to 16.

In FIG. 2, (S202) the set point can alternatively be a non-physically meaningful, arbitrarily chosen value. The decision to do this may be driven by a preference to achieve a particular higher-level behaviour (e.g. charging time, battery life, battery lifetime, for example with the knowledge that in doing so either (1) excessive degradation will occur or (2) a large degree of “headroom” remains and the full performance is possibly not exploited). Such an approach is different in the sense that the choice is not directly driven by degradation (avoidance) goals.

FIGS. 1 and 2 present an example where the invention resided within a battery management system, which may for example be applicable to an electric vehicle. In this context, an electric vehicle is intended to include any urban or road vehicle, such as electric cars, battery assisted bicycles, scooters, delivery or vehicles, as well as vehicles/delivery systems for aerospace or water based applications. In the same example, a similar but alternative implementation where the charger makes the decision of the charging current to provide to the battery, instead of the battery management system making that decision, the invention may reside within the charger. An example of such a scenario may be a cordless power tool charger wherein the charger decides what current to supply to a cordless power tool's battery pack.

Although some features of the invention make it particularly suitable for use on embedded systems, the invention need not reside on an embedded system (e.g. battery management system or charger) and may instead reside on a computer elsewhere (e.g. the “cloud”) and be remotely connected to an application in a real-time, near-real-time, or non-real-time control process.

### Battery Control System Embodiment

Based on the above discussion of overpotential fraction maps and calculation of the instantaneous negative and positive electrode potentials, discussion will now be made of an example battery control operation that may be implemented by the apparatus shown in FIG. 1. As noted above, it can be advantageous to control the charging/discharging of the battery based on electrode potential set points in order to avoid excessive degradation of the battery, or to control other parameters such as charging speed or charging power.

FIG. 10 is a functional block diagram illustrating a battery control frame work according to an embodiment of the invention. It will be appreciated that the steps and functional blocks of the framework may be implemented in software and/or the hardware of FIG. 1 for example, as discussed above.

Referring to FIG. 10, Control block 1008 is responsible for controlling the charging or discharging of the attached cell or battery. The Control block 1008 takes as an input an indication of the attached battery's negative and/or positive electrode potential from the State Estimator block 1004, as well as one or more control set points from Settings block 1006. The Settings block 1006 allows a user to enter control set points, such as one or more negative electrode potential set points, one or more positive electrode potential set points, and optional further control set points such as terminal current and terminal voltage set point, to control the charging and discharging process carried out by the Control block 1008. Based on the inputs from the Settings block 1006 and the State Estimator block 1004, the Control block 1008 outputs control signals to control the charging and/or discharge current, and/or the charging and/or discharge voltage for the battery. It is noted that this output may be considered in the light of other limits or constraints such as those imposed by software or hardware elsewhere in a larger system, for example to enforce safety or other control measures.

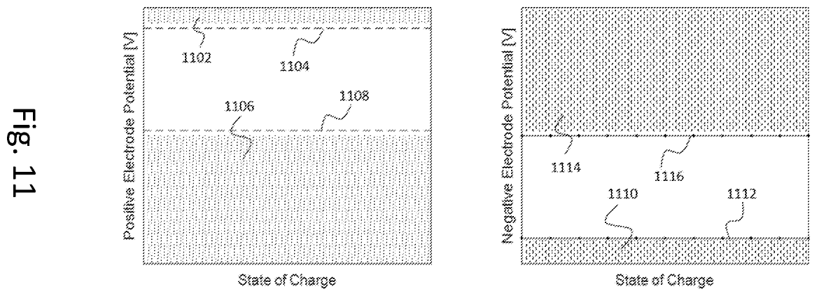

In operation, the Settings block 1006 receives an indication of the desired set points for one or more of the positive or negative electrode potentials. The indication may be specific electrode potential values, as will be discussed later with reference to FIG. 11. Alternatively the indication may be of a desired charging/discharging mode for the connected battery. Depending on a selected charging/discharging mode, the Settings block 1006 subsequently selects prestored set points suitable for the mode. As discussed below, the set points may be different depending on whether the charging/discharging process is intended to focus on preserving battery health, or performance. The Settings block 1006 also allows a user to manually enter details of the connected battery if this cannot be determined from the parameters measured by the Measurement block 1002

The Measurement block 1002 determines from the connected battery, one or more battery parameters indicating the present state of a connected battery. The battery state parameters including one or more of the instantaneous battery potential, the battery current, and the battery temperature for example, and are straightforward to measure. These parameters are passed to the State Estimator block 1004 for use in calculating the state-of-charge for the battery, and the associated instantaneous negative and positive electrode potentials. It will be appreciated that as the charging/discharging process continues, the parameters measured by the Measurement block 1002 and calculated by the State Estimator block 1004 will change.

The State Estimator block 1004 uses an over potential fraction map for the attached battery to estimate in real time the negative electrode potential and positive electrode potential for the attached battery. A technique for producing the over potential fraction map is discussed above. The State Estimator block 1004 estimates the negative and positive electrode potentials based on a number of physical battery attributes measured in real time, including the battery current, the battery voltage, and the battery temperature, measured on a cell, module or pack terminals, using one or more over potential fraction maps stored in memory. The overpotential fraction map may be stored in memory as a function of the state-of-charge of the connected battery. Thus, the State Estimator 1004 may determine the state-of-charge for the connected battery based on the parameters received from the Measurement block 1002. Alternatively, the Measurement block 1002 may measure or determine the state-of-charge for the connected battery and pass this to the State Estimator block 1004. As noted above, the state-of-charge of the battery is not typically a directly measurable quantity, and many methods exist for its estimation. An example is “coulomb-counting”, whereby current is measured with a sensing device such as a shunt resistor, and charge throughput is recorded and used to estimate state-of-charge.

The State Estimator block 1004 estimates the negative and positive potential electrode potentials, which allows these parameters to be used with set points for the real-time charging/discharging Control block 1008, such that the maximum charge/discharge current or maximum/minimum charge/discharge voltage can be bounded by these set points.

When the battery is in equilibrium, i.e. when no current is passing through and it has been rested for a sufficiently long time, the battery's terminal voltage V_{cell} is the open-circuit voltage U_{cell}. When the battery is under load, i.e. a current is passing through, the battery's terminal voltage is influenced by the overpotential η_{cell} as described in Equation 13 below. Similarly for the open-circuit positive electrode potential Uₚₒₛ, the positive electrode potential under load Vₚₒₛ, the open-circuit negative electrode potential U_{neg}, the negative electrode potential under load V_{neg} and their respective electrode overpotentials ηₚₒₛ and η_{neg}, the relationships are described in Equations 10 and Equation 11 presented above.

$${V}_{c e l l} = {U}_{c e l l} + {η}_{c e l l} \qquad Equation 13$$

$${V}_{p o s} = {U}_{p o s} + {η}_{p o s} \qquad Equation 10$$

$${V}_{n e g} = {U}_{n e g} + {η}_{n e g} \qquad Equation 11$$

The State Estimator block 1004 relies on the overpotential fraction map, which is pre-calibrated using the reference battery cell and available or pre-loaded in memory. The two overpotential fractions for positive electrode η_{f,pos} and for negative electrode η_{f,neg} are defined in Equation 8 and Equation 9 discussed earlier.

$${η}_{f , pos} = \frac{{η}_{p o s}}{{η}_{cell}} \qquad Equation 8$$

$${η}_{f , neg} = \frac{{η}_{n e g}}{{η}_{cell}} \qquad Equation 9$$

Measurements of the open circuit voltage U_{cell}, the open-circuit potentials Uₚₒₛ and Uₚₒₛ are determined across the full state-of-charge range for a reference battery and included in the State estimator block 1004. Values for U_{cell}, Uₚₒₛ and Uₚₒₛ can then be looked-up in real-time with reference to state-of-charge, temperature, current or/and other relevant physical quantities. The real-time terminal voltage Vcell is directly measurable, with the system of FIG. 1. Therefore, using Equations 11 to 13 and 8 and 9, the real-time electrode potentials Vpos and Vneg can be determined in the State Estimator block 1004.

To initiate a charging or discharging operation, the user may therefore specify particular desired set points for the negative electrode potential and positive electrode potential set points in order to optimize the charging/discharging process. The user may do this by selecting a charging/discharging mode such that predetermined set points are applied. Different set points allow different priorities to be reflected in the charging/discharging process. Such priorities typically mean rebalances of performances, for example charge time, usable energy/runtime, safety margins and degradation rates etc.

FIG. 11 shows schematically a desired range of operating potentials for the positive and negative battery electrodes. The vertical axis on the diagram shows increasing values for electrode potential. In this non-limiting example, the values on the vertical axis may be understood to vary from 0V to 5V. In other applications, the values may differ. The x axis indicates the state-of-charge of the connected battery. In practice, the optimal sets point will have a dependency on the state-of-charge of the connected battery, and will be a function of other battery state parameters. For the present discussion and for everyday applications it is sufficient to approximate the applied set points to be the same across the range of available state-of-charges.

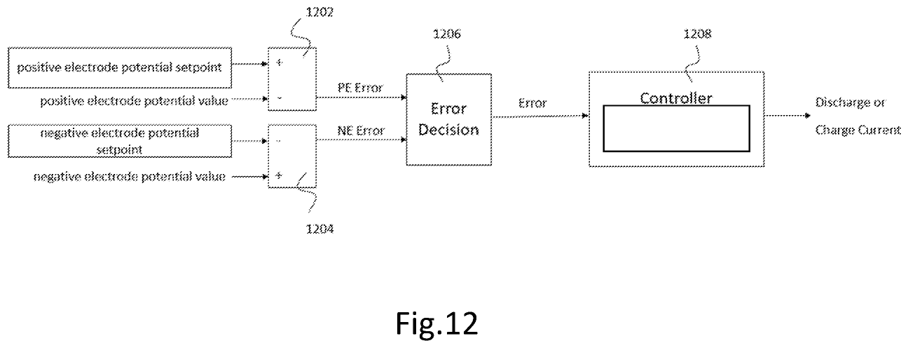

Referring again to FIG. 11, the positive electrode potential set point 1104 represents the upper bound of the positive electrode potential and 1108 the lower bound during normal, optimal use of the battery. Keeping within the range of electrode potentials defined by 1104 and 1108 therefore ensures that the battery electrodes are not unduly degraded during charging/discharging operations. The shaded areas indicated by 1102 and 1106 represent non-operating regions that the battery's positive electrode potential should not enter. Ensuring that the battery's positive electrode potential remains in the bounds set by 1104 and 1106 is possible by controlling the voltage and current in real-time, as further detailed in FIG. 12. Generally speaking, ensuring that the instantaneous positive electrode potential does not cross the upper set point 1104 ensures that during charging the positive electrode is not subjected to electrochemical, mechanical and other process that would result in damage. The same is true of the lower threshold 1108 during discharging processes.

Similarly, for the negative electrode potential, the set point 1112 represents the lower bound of the desired negative electrode potential and the set point 1116 the upper bound. During charging processes, keeping the instantaneous negative electrode potential above the lower threshold or set point 1112, means the negative electrode is not subjected to potentials that would cause damage. The same is true of the upper set point or bound 1116, during discharging operations. Again, the shaded areas indicated by 1110 and 1114 are non-operating regions.

During battery charging, set point 1104 for the positive electrode potential and set point 1112 for the negative electrode potential are often sufficient to ensure that the charging process completes in an optimal manner. In other words, it is not necessary to always define lower voltage set points.

Similarly, during battery discharging, set point 1108 on the positive electrode potential and set point 1116 on the negative electrode potential are often sufficient to ensure that the discharging process can be carried out optimally. The apparatus shown in FIG. 1, and the functional diagram shown in FIG. 10 therefore allows the user to choose to impose one or more set points (1104, 1108, 1112 and 1116) depending on the requirement or mode of the application.

As noted above, the battery charging method allows for different battery charging/discharging modes to be selected, with the corresponding positive and negative electrode set points for each mode varying accordingly. Generally speaking, more conservative charging/discharging processes, such as those that prioritize battery health and prevent degradation to the battery, have a narrower range of operating electrode potentials between the maximum and minimum set points for the respective positive and negative electrodes. For applications, that favour performance, the bounds can be set further apart.

FIG. 12 is a schematic diagram showing a control process for implementing the user defined set points in a controlled charging or discharging process. The control process is based on a combined error approach, and FIG. 12 therefore represents a technique for implementing the control process in software.

The combined error is calculated by the Error Decision functional block 1206 on the basis of positive electrode error and negative electrode error signals received as inputs.

The positive electrode error is calculated by the difference between the positive electrode potential set point and the actual positive electrode potential value 1202. Similarly for the negative electrode potential, the negative electrode error is the difference between the negative electrode set point and the actual value 1204 at a moment in time. In this regard, during the charging process only the upper of the positive and negative potential set points may be needed. A negative error in 1202 or 1204 indicates that the value of the actual positive electrode potential or the actual negative electrode potential is in the non-operating region represented as 1102 and 1110 in FIG. 11.

A combined error formed from a summation of the two errors is calculated in 1206 and output to the Controller block 1208. As the error signals are varying in real time, the combined error value can be determined via a number of different possible algorithms. A simple example is to choose the minimum from both errors in summation blocks 1202 and 1204 for a periodically updating time window. An error decision based on the potential of both electrodes is then provided to the controller 1208. The controller may employ an anti-windup scheme if desired. Some example of applicable controllers include 1) a proportional-integral-derivative (PID) controller; 2) a reference governor; and/or 3) a full model predictive control (MPC).

In the Controller block 1208, an appropriate charge or discharge current is then determined for the next instant of battery operation, to bring the error in 1206 closer to zero. In the case of charging, an increase in charging current accelerates the increases in the actual positive electrode potential and decreases the actual negative electrode potential, and vice versa. The sign and magnitude of the current is adjusted accordingly to prevent the positive and negative electrode potentials from entering the non-operating regions illustrated as 1102 and 1106, 1110 and 1114 in FIG. 11.

Additionally, when the optional terminal current set points and the optional terminal voltage set points in Setting Block 1006 illustrated in FIG. 10 are in place, they provide the additional operational bounds for determining the discharge/charge current and discharge/charge voltage. The optional terminal current and voltage bounds can be in place for warranty and safety requirements or a further limitation on degradation.

The functional blocks illustrated in FIG. 12 assume a battery charging process. The control framework in FIG. 12 can also be applied to other situations, including:
1) Electrode-potential controlled discharge, by imposing a high negative electrode potential threshold and/or a low positive electrode potential threshold;
2) Electrode-potential controlled operations by imposing the upper and lower electrode potential set points on both positive electrode and negative electrode.
3) Periodic or one-off adjustment of battery electrode potentials during storage to minimise calendar aging.

It should be noted that even though the example in FIG. 11 illustrate a control scenario in which the electrode potential set points are fixed, the set points can also be implemented as a function that varies with state-of-charge, the terminal voltage, temperature and any other physical state of the battery. More generally, the set points can be chosen based on one or more of the following criteria:
a) the thermodynamic and kinetic potential thresholds that trigger or accelerate adverse degradation mechanisms on the electrodes. For example, lithium plating on the negative electrode has a thermodynamic potential threshold at 0 V. When the negative electrode potential goes below 0 V, this can happen. 0 V is a sensible negative electrode potential lower set point as 1112 in FIG. 11 in order to mitigate lithium plating. Major adverse degradation mechanisms include graphite exfoliation on the negative electrode, structural disordering and transitional metal dissolutions on the positive electrode, and pore blockage and particle fracture on both electrodes;
b) the potential required to achieve the required power and energy for the applications. For example, with reference to FIG. 11, during charging if the application has a priority on obtaining high energy with acceptable compromise on lifetime, setpoint 1112 in FIG. 11 on the negative electrode potential is then decreased to −20 mV, which allows a minor extent of lithium plating to happen as the potential goes below 0 V but brings additional gain on both the rate of energy charged and the total energy charged;
c) the potential above or below which reactions that cause safety issues, such as. fire and gassing, happen or are likely to happen. One example of such reactions is thermal runaway. For example, high-nickel positive electrode has a high probability to initiate thermal runaway at 5 V. The setpoint 1104 in FIG. 11 on the positive electrode potential is set to be 5 V for safety protection and also to give warming when the state estimator block 1004 in FIG. 10 detected a positive electrode potential above this set point.

The specific potentials mentioned above will change with the battery's temperature, temperature gradient and the electrodes chemistries. Again, the control software can be implemented with algorithms that incorporate all of these parameters.

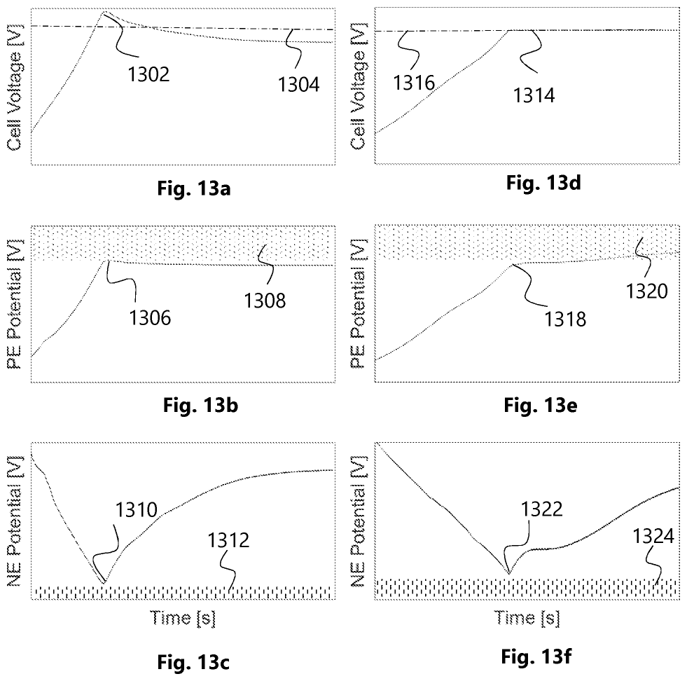

FIG. 13 for example illustrates cell voltage against time charts for positive-electrode potential controlled charging as described above (left diagrams FIG. 13a to FIG. 13c) with known constant current (CC)-constant voltage (CV) charging techniques (right diagrams FIG. 13d to FIG. 13f). The different behaviours and the advantages of electrode-controlled charging are listed below.

In the positive electrode potential controlled charging, the potential electrode potential hits its set point at 1306 and then maintains a plateau at the positive electrode potential set point afterwards. This is illustrated in the middle left hand diagram FIG. 13b. In the known CC-CV charging techniques however, the control decision is based on the terminal cell voltage instead, where the cell potential hits its set point at 1314 and keeps a constant cell voltage plateau at this set point. This case is illustrated in the top right diagram FIG. 13d.

In the positive electrode potential controlled charging, after reaching the positive electrode potential set point at 1306, the positive electrode potential remains outside of the non-operating region marked by the shaded area 1308. However, in the case of CC-CV charging, after the cell terminal voltage reaches its set point at 1314, the positive electrode potential still keeps increasing after 1318, eventually going into the non-operating region 1320. This is undesirable for minimising positive electrode degradation.

Now referring to the negative electrode potential shown in the bottom row of diagrams (FIGS. 13c and 13f), when the positive-electrode potential set point is reached at 1306, the negative potential also reaches a minimum at 1310, subsequently relaxing back to a higher value, and eventually plateauing-off.

In the known CC-CV technique, when the cell terminal voltage set point is reached at point 1314, the negative electrode potential reaches a minimum at 1322 and then rises to a higher value, increasing further until the end of the CV phase. In both scenarios, the negative electrode behaviours are acceptable as both show an increase after the reaching the set point and neither enter the non-operation regions 1312 and 1324. As a result, neither of the negative electrode charging scenarios illustrated in FIGS. 13c or 13f are likely to trigger excessive degradation such as lithium dendritic deposition.

Referring again to the top right diagram FIG. 13d, the cell terminal voltage set point in CC-CV charging is indicated by the dotted line 1316. It is reproduced in the top left hand diagram FIG. 13a as the dotted line 1304 in the case of positive electrode potential controlled charging. The cell terminal voltage in the case of positive-electrode potential controlled charging momentarily peaks above the line 1304, but both electrode potentials steer away from the non-operating regions 1308 and 1312 over time. A temporary overshoot in cell terminal voltage is permissible in terms of minimising degradation and this allowance can speed up charging and gains slightly on energy density.

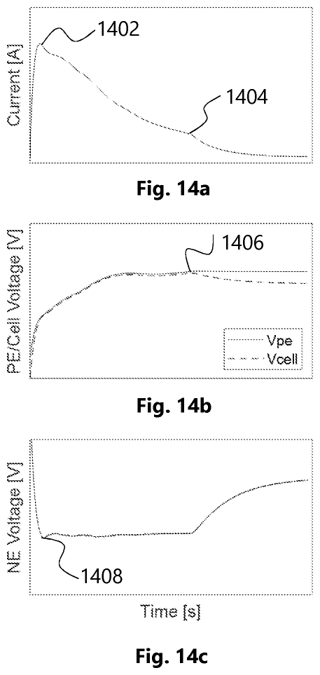

FIG. 14a illustrates the charge current variations in a charging process when both a positive electrode potential set point and a negative electrode potential set point are in effect. Corresponding variations in the positive electrode potential and cell potential are illustrated in FIG. 14b. The corresponding negative electrode potential is illustrated in FIG. 14c. The first instance of current reduction at 1402 is predominantly determined by the error in the negative electrode potential as calculated in the summation block 1204 of FIG. 12. The negative electrode potential reaches its set point at 1408 and afterwards is stabilised by the controller at its set point value.

At the second instance of current reduction 1404, the positive electrode potential error in 1202 in turn becomes dominant as the positive electrode potential reaches its set point at 1406. The charge current is more aggressively reduced at 1404, which is evident from a steeper gradient of the current decrease from this point onwards. Eventually as the positive electrode potential reaches a plateau and the current goes down to the cut-off current threshold, the charging is complete.

Thus, as illustrated in FIG. 14, it can be effective to have both positive and negative electrode potential set points in place. It also demonstrates that when both electrode potential set points are in place, the cell terminal voltage V_{cell}, is also controlled, as the relationship between the cell terminal voltage and the individual electrode potentials is described by Equation 14 below. It is then possible to disregard V_{cell} as the main control parameter, focussing on the respective electrode potentials instead.

$${V}_{c e l l} = {V}_{p o s} + {V}_{n e g} \qquad Equation 14$$

For fast charging applications, it is also possible to disregard maximum current limits, which are usually imposed in known control methods. The current at each instance is determined by the positive electrode potential set point(s) and the negative electrode potential set point(s), which are used to dynamically calculate the maximum current based on the present battery state without causing electrode-related degradation or safety issues.

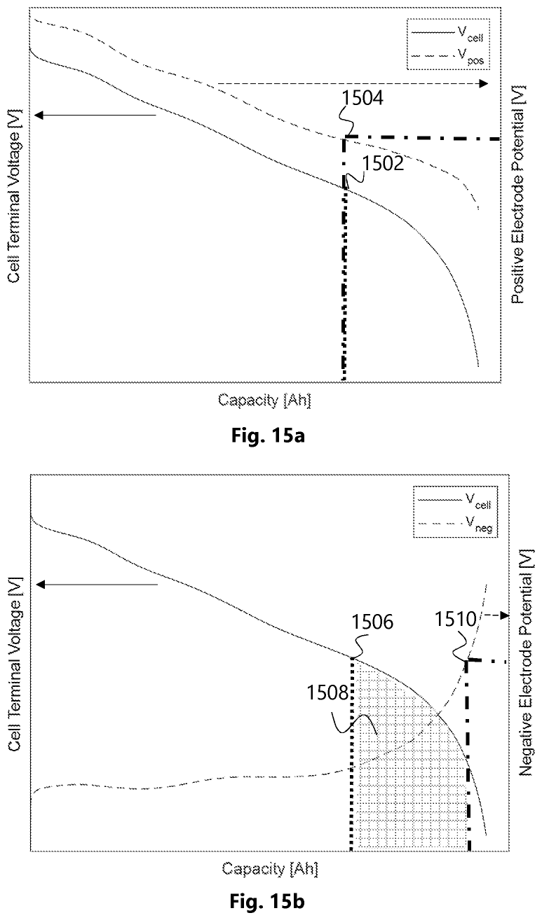

FIGS. 15a and 15b illustrate a comparison between a battery discharge operation governed by a cell terminal voltage set point, and a battery discharge operation governed by electrode potential set point(s). Two cases are illustrated, as follows:

(1) the top figure, FIG. 15a, illustrates an example in which the priority is to minimise electrode-related degradation. In battery state-of-health (SOH) applications such as this one, the performance of a degraded or aging battery is understood relative to the performance of a fresh battery, with the aim being to prevent the performance of the aging battery from degrading further.

The known approach is to control the discharge by using a cell terminal voltage set point at 1502. However, where the positive-electrode-related degradation is of concern, the positive electrode potential set point 1504 can be used to replace or supplement the cell terminal voltage set point 1502 for more accurate control. The positive electrode potential 1504 corresponds to the point where cell terminal voltage reaches 1502 at the equivalent state-of-charge for the battery when the battery is fresh. Further, the advantage is that tracking 1504 with a state-of-health measure (detailed in the next section), more accurately prevents the positive electrode potential going too low and triggering undesirable reactions such as crystal structure changes, than tracking the cell terminal voltage 1502. This is so because at a lower state of health, stopping discharge at 1502 may no longer prevent the positive electrode potential from going below 1504. This can occur for various reasons, including for example resistance changes at an electrode, or stoichiometric drift. The cell terminal voltage set point is a combination of both electrode potentials as shown in Equation 14, and hence it is difficult to determine whether the individual electrode potentials are remaining within acceptable bounds from the cell terminal voltage alone.

Similar negative electrode set point(s) can be applied during discharge operations to prevent undesirable negative electrode reactions, such as solid-electrolyte-interphase decomposition. Although FIG. 15 illustrates an example where end-of-discharge is controlled, the same approach may be applied to control end-of-char

(2) the bottom FIG. 15b illustrates an example in which the priority is to maximise discharge energy. Instead of setting a cell terminal voltage set point 1506, a negative electrode potential set point 1510 is set, which is the maximum negative electrode potential permittable without causing excessive degradation. As shown in the shaded area 1508, there is a considerable energy gain by setting the negative electrode potential to the highest permittable set point 1510 rather than setting the cell terminal voltage 1506.

Similar positive electrode potential set point(s) can be applied in discharge to maximise energy by setting the lowest permittable positive-electrode potential set point.

It should be noted that although the examples in FIGS. 15a and 15b only illustrate set points on one of the electrodes, set points on both electrodes can be applied simultaneously.

In real operations, it is often possible to have both energy gain and degradation minimization by switching to electrode-potential controlled discharge from terminal voltage controlled discharge.

### Methods of Qualitative Assessment on State of Health (SOH) and Adaption to SOH

As batteries experience degradation with time and/or cycle numbers, the open-circuit potentials U_{cell}, Uₚₒₛ and U_{neg} are also subject to change. When a slow charge or discharge, for example C/10 or C/15, is performed, the recorded cell terminal voltage post-degradation is assumed to be close approximation of the cell's open-circuit voltage U_{cell,deg}. To determine whether the control algorithm for the battery requires an update, the following error e is calculated across the operational state-of-charge window as shown in Equation 15.

$$e = {U}_{cell , degraded} - ( {U}_{p o s} - {U}_{n e g} ) \qquad Equation 15$$

The (Uₚₒₛ−U_{neg}) term provides the cell's open circuit voltage at its fresh state U_{cell}. A non-zero e indicates that the system would benefit from an update, while the absolute value of the error e indicates the magnitude of deviation of the post-degraded open-circuit potentials from their values at the fresh state.

The following two steps detail how an update may be carried out:
(1) The cell's open-circuit voltage U_{cell} in memory is replaced by U_{cell,degraded} measured on a slow charge or discharge
(2) An optimization is performed based on Equation 15 to adjust Uₚₒₛ to the post-degraded U_{pos,degrade} and U_{neg} to the post-degraded U_{neg,degrade}, such that the absolute value of the error value e is reduced towards zero. Subsequently, Uₚₒₛ is replaced by U_{pos,degrade} and U_{neg} by U_{neg,degrade}.

The frequency at which the update should be carried out can be determined by the threshold absolute values of the error value e, above which an update is required, a schedule of fixed time periods, e.g. monthly, or a schedule based on other physical quantities of the batteries indicating the state-of-health, for example 5% loss in the charge capacity measured at 1 C or 10% increase in internal resistance at 50% state-of-charge.

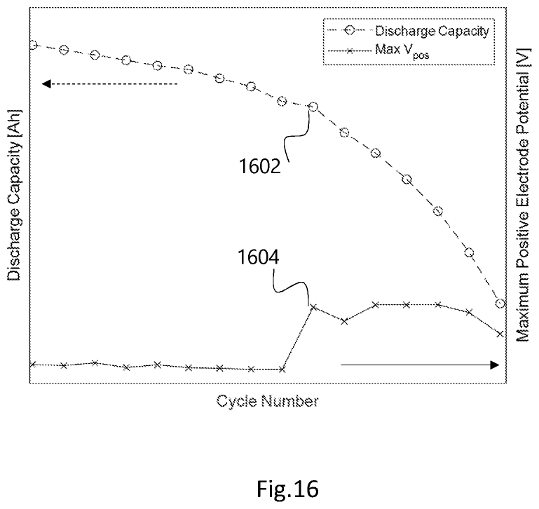

Besides being incorporated in battery control systems, the State Estimator block 1004 can also be used as a battery state-of-health (SOH) indicator. This is illustrated in more detail in FIG. 16, which shows, by way of example, the positive electrode potential being used as a SOH indicator.

The most widely-used SOH indicator is the charge/discharge capacity. As batteries degrade, the discharge capacity, shown in FIG. 16 by the open circles, decreases, and at 1602, reaches a critical point when the capacity drops drastically. This is often referred to as capacity ‘roll-over’.

As discussed above, the positive electrode potential is determined in the State Estimator 1004 in real-time, and the maximum positive electrode potential max Vₚₒₛ reached by the battery at each cycle is recorded. At 1604, the maximum positive electrode potential reaches at each cycle experiences a sudden increase. This corresponds to the capacity ‘roll-over’. Hence, the maximum positive electrode potential is also a viable and trackable SOH indicator.

As illustrated in FIG. 16, a sudden change in the maximum and minimum individual electrode potential can be caused by the onset of particular degradation mechanisms in the battery electrodes, such as structural decomposition on the positive electrode. This sudden change can sometimes be self-accelerating and in the worst case, triggers the roll-over. For example, the positive electrode reaches a higher potential due to local structural decomposition and the exposure to high potential in turn causes more structural decomposition. In the State Estimator block 1004 the degradation related step change in the positive electrode potential illustrated in FIG. 16 can therefore be detected by monitoring changes in the calculated maximum electrode potential over time. If the changes in the maximum electrode potential exceed a threshold value then the State Estimator 1004 may determine that roll-over has occurred. A similar procedure may be carried out for changes in the negative electrode potential.

Individual electrode potentials are therefore useful as supplementary SOH indicators in addition to the measurable discharge/charge capacity, when there is not sufficient time to carry out capacity measurements across the full voltage range, and when there is transient but recoverable capacity fade. It also allows an understanding of which electrode (negative or positive electrode) is primarily causing the degradation.

### Methods of Qualitative Assessment of State of Available Power (SOAP)

The state of available power (SOAP) is the battery's power capability at the present SOC and SOH. The fundamental equations underlying the state-of-the-art calculation of state of available power are shown as Equation 16:

$$\{ \begin{matrix}{P}_{dch} = {V}_{cell , min} \cdot ( {U}_{cell} - {V}_{cell , min} ) / {R}_{cell , dch} \\ {P}_{chr} = {V}_{cell , max} \cdot ( {V}_{cell , max} - {U}_{cell} ) / {R}_{cell , chr}\end{matrix} \qquad Equation 16$$

where the P_{dch} is the state of available power for discharge, P_{chr} is the state of available power for charge, V_{cell,min} is the minimum cell terminal voltage set point, V_{cell},min is the maximum cell terminal voltage set point, R_{cell,dch} is the battery impedance during discharge and R_{cell,chr} is the battery impedance during charge.

Equation 16 is influenced by the cell open-circuit voltage and its set points. Therefore, the SOAP calculation can be based on the individual electrode potentials from the State Estimator block 1004, as described in Equation 17 below with the positive electrode potential and in Equation 18 with negative electrode potential.

$$Equation 17 :$$

$$\{ \begin{matrix}{P}_{dch} = {V}_{pos , min} \cdot \frac{{U}_{pos} - {V}_{pos , min}}{{R}_{cell , dch}} & ( 17.1 ) \\ {P}_{chr} = {V}_{pos , max} \cdot \frac{{V}_{pos , max} - {U}_{cell}}{{R}_{cell , chr}} & ( 17.2 )\end{matrix}$$

$$Equation 18 :$$

$$\{ \begin{matrix}{P}_{dch} = {V}_{neg , min} \cdot \frac{{U}_{neg} - {V}_{neg , min}}{{R}_{cell , dch}} & ( 18.1 ) \\ {P}_{chr} = {V}_{neg , max} \cdot \frac{{V}_{neg , max} - {U}_{cell}}{{R}_{cell , chr}} & ( 18.2 )\end{matrix}$$

In Equation 17 and 18, Rpos,chr is the impedance of the positive electrode during charge and Rpos,dch the impedance of positive electrode during discharge. Rneg,chr is the impedance of the negative electrode during charge and Rneg,dch the impedance of the negative electrode during discharge. V_{pos,max} is the maximum positive electrode potential setpoint and Vpos,min the minimum. Similarly for V_{neg,max} and V_{neg,min} for the negative electrode potential.

The electrode-potential based SOAP calculation can be based on:
a) Equation 17.1 and 17.2, for prioritizing positive electrode stability;
b) Equation 18.1 and 18.2, for prioritizing negative electrode stability;
c) Equation 17.1 and 18.2, for prioritizing positive electrode stability during discharge and negative electrode stability during charge;
d) Equation 17.2 and 18.2, for prioritizing positive electrode stability during charge and negative electrode during discharge;
e) The minimum from Equation 17.1 and Equation 18.1, and the minimum from Equation 17.2 and 18.2, for accounting for both electrodes throughout charge and discharge.
   The advantage of electrode-potential based SOAP is that it gives more accurate power estimation which account for the stability windows of the electrodes and the adaptation to state-of-health detailed in the previous section can be incorporated as well. This can provide a wider power envelope and/or better protection of the battery health.

### Alternative Embodiments

Returning now to the discussion of overpotential fraction calculations in FIGS. 1 to 10, instead of using the overpotential maps for the estimation of electrode potential in the manner described, the overpotential maps can alternatively: be used to estimate the overpotential at each electrode which can be summed to produce an estimate of the cell overpotential, which in turn may be used for many possible means, such as to estimate when a voltage limit will be reached, or to be used in estimating the amount of energy loss (inefficiency), or to estimate heat generation. That is, the maps enable estimation of battery efficiency and polarisation extent.

As with the adaptation of invention parameters to battery degradation, control process parameters may additionally be updated. For example, the set point may be updated to provide a consistent or a wider safety margin later in the life of the battery. Example; a consistent safety margin on charging may be beneficial for when the invention is used to control the charging current through the life of an electric vehicle whose battery will exhibit degradation.

When open-circuit data such as 302, 304, and 306, are recorded and stored in computer memory, it is not necessary that a single open-circuit potential profile is stored for each of the electrodes and cell for use in estimating electrode potentials during both charging and discharging. That is, a separate (and different) open-circuit potential profile may be stored for use during each of charge and discharge. This is particularly so for batteries which may exhibit relatively large hysteresis in open-circuit potential profiles, for example, some batteries whose graphitic negative electrodes contain silicon.

The open-circuit data such as that in 302, 304, and 306 may additionally be defined as a function of temperature and/or battery health, such that it is acquired in embodiment 702 under these different conditions (e.g. at a different temperature such as 0 degrees Celsius or 40 degrees Celsius, at a different battery health level such as when the battery retains only 90% of its original capacity) and additionally stored in computer memory. Although this increases the memory requirements, it may be advantageous, particularly if updating of the open-circuit-potential data during the battery operation is expected to be difficult.

The overpotential fraction maps of FIG. 8 are shown as functions of state-of-charge and of current (i.e. where a unique map is provided for each of two different current levels). These maps may additionally be functions of temperature, of battery health or degradation state, and other properties, in addition to being a function of state-of-charge and current. These additional dependencies are useful for enhancing the accuracy of the map values obtained under different conditions. To construct the overpotential maps over these different variables, steps S702 to S708 inclusive are repeated under the different conditions (e.g. at a different temperature such as 0 degrees Celsius or 40 degrees Celsius, at a different battery health level such as when the battery retains only 90% of its original capacity). A basic map may therefore be a two-dimensional representation consisting of overpotential fraction for an electrode versus state-of-charge. A more advanced map may be five-dimensional, consisting of overpotential fraction for an electrode versus the following further four axes: (1) state-of-charge (exemplary range 0-100%), (2) temperature (exemplary range −10 to +45 degrees Celsius), (3) current (exemplary values 0.5 C to 5 C) and finally, (4) cell state-of-health defined by the fraction of the as-new capacity remaining (exemplary range 100% to 50%).

### CONCLUSION

The embodiments of the invention discussed above require a very low number of parameters in order to estimate electrode potentials. Specifically, only 1) open-circuit potential vs. state-of-charge profiles for the cell and for each electrode 2) an overpotential fraction map (overpotential fraction vs. state-of-charge) for one or each electrode. i.e. a minimum requirement of four parameters are needed. This low parameterisation requirement provides a number of benefits:

(1) Low financial and time cost (hours to days) to obtain the necessary parameters from any battery. This is in contrast to the high parameterisation requirements (weeks to months) for alternative methods of model-based electrode potential estimation, such as electrochemical “full-order” continuum battery models and even their reduced-order variants, which often require tens of parameters.

(2) Greater adaptability of parameters to battery degradation: because of the low parameter requirement (and because the parameters are relatively easily obtained) the parameters are relatively easy to update as a battery degrades during its life. This is an important advantage. The fewer parameters required initially, the larger the number or fraction of them that are likely to be able to be obtained in-situ later in the battery's life, leading to better and/or more consistent performance from the invention. For example, all three open-circuit potential parameters (full-cell & both electrodes)—approximately three-fifths to three-quarters of the total parameter set—can be updated during the life of the battery by performing a simple slow charge. It is not possible to update in-situ experimentally many of the tens of parameters required for alternative model-based approaches to electrode potential estimation.

(c) Ease-of-parameterisation: those few parameters which are required are relatively easy to obtain. That is, the open-circuit potentials and overpotentials required can be obtained with a relatively simple reference electrode full-cell, in contrast to the far wider range of experiments, often requiring an array of more expensive specialist equipment, needed to obtain parameters for alternative approaches. Not only is this cheaper and faster initially, but it supports in-situ updating of parameters when the battery is in use/during the life of the battery.

(d) Computationally lightweight. The invention requires few computational resources (processing power and computer memory). These features provide benefits that include allowing the invention to be used on hardware including microcontrollers in embedded systems where minimisation of cost, power consumption and/or volume are desirable. For example, a microcontroller functioning as the battery management controller 10, whose total memory is measured in hundreds of kilobytes and whose processor clock speed is measured in low hundreds of MHz, an example being a Texas Instruments™ unit of the TMS570 family, is sufficient for operation of the invention. It will be appreciated that the invention is not restricted to such a hardware type or performance level, but that this serves as one possible example.

Further, the use of cell overpotential as a major element in the determination of electrode potential estimates means that the invention inherently exhibits a degree of adaptivity to battery degradation. This is because as a battery degrades, that degradation typically manifests as a change in the battery resistance and a change in the overpotential. By taking this into account when making electrode potential estimates, the invention is differentiated from other approaches to battery control which do not exhibit this adaptivity, such as the use of pre-determined charging current profiles defined over time or a state-of-charge window, or the use of look-up tables of electrode potentials as functions of, for example, state of charge. In effect, this adaptivity of electrode potential estimates to degradation substantially widens the range of operational validity of the invention.

Lastly, owing to the analytical nature of the equations for estimating electrode potentials, the electrode potential solution process possesses high mathematical and numerical stability. This has the higher-level effect of ensuring a high level of reliability, dependability and overall increased safety.

The embodiments and examples discussed above are illustrative and not intended to limit the invention as defined by the following claims.

### Supplemental Notes

Further aspects of the Invention are presented below as supplemental notes 1 to 19.

(1) In a first aspect, a battery management method is provided for charging or discharging a connected battery, and/or for use in a battery diagnostic method, using non-equilibrium potentials for one or more of the negative and positive electrodes determined for the battery, the battery management method comprising the steps of:
determining for a connected battery one or more battery state parameters indicating the present state of the connected battery, the battery state parameters including at least the instantaneous cell potential and the state-of-charge of the connected battery;
   estimating for the connected battery, based upon the determined state-of-charge, one or more of: the battery open-circuit potential, and the open-circuit electrode potentials for the negative and/or positive electrodes;
   determining the overpotentials for the one or more of the positive and negative electrodes of the connected battery, based on the estimated open-circuit potential for the reference battery, by referring to a reference overpotential fraction representation that is available in memory and which maps the respective state-of-charge values for the reference battery to the corresponding fractions of the battery overpotential that are attributable to the negative and the positive electrodes;
   determining the non-equilibrium electrode potentials for the one or more of the negative and positive electrodes of the connected battery, based on the estimated open-circuit potential of the negative and/or positive electrodes of the reference battery, and the overpotentials for the respective negative and/or positive electrode;
   controlling the charging or discharging of the battery, or determining one or more parameters indicative of battery health depending on the determined non-equilibrium potentials for the one or more of the negative and positive electrodes.

(2) Further, the method of note (1), wherein estimating one or more of the battery open-circuit potential, and the open-circuit electrode potentials for the negative and/or positive electrodes, comprises: based upon the determined state-of-charge for the connected battery, referring to a reference open-circuit potential representation that is available in memory, which maps the respective state-of-charge values for a reference battery to the corresponding values of open-circuit potential for the reference battery, and for the negative and positive electrodes of the reference battery.

(3) Further, the method of note (1) or (2), wherein determining the non-equilibrium electrode potentials for the one or more of the negative and positive electrode potentials comprises summing (S914) the open-circuit electrode potentials for the negative and positive electrodes with the overpotentials for the negative and positive electrodes.

(4) Further, the method of note (1), (2) or (3), wherein determining the overpotentials for the one or more of the negative and/or positive electrodes comprises combining (912) a value for the battery overpotential with an overpotential fraction value indicating the respective fractions of the battery overpotential attributable to the negative and the positive electrodes.

(5) Further, the method of note (4), wherein determining (S906) the battery overpotential comprises determining (S906) the difference between the determined cell potential for the connected battery and the open-circuit potential for the reference battery.

(6) Further, the method of any preceding note, wherein the battery state parameters further include one or more of battery temperature, charging current, and state of health.

(7) Further, the method of any preceding note, wherein reference open-circuit potential representations and reference overpotential fraction representations are determined for a plurality of different reference batteries and stored in memory.

(8) Further, the method of any preceding note, comprising generating the open-circuit potential representation by monitoring the electrode potentials of a reference battery or a half cell reference battery for a range of state-of-charge values.

(9) Further, the method of any preceding note wherein the determined state-of-charge for the connected battery is used in place of the state-of-charge of the reference battery to look up the corresponding values in the open-circuit representation or the overpotential representation.

(10) In a second aspect, there is provided a battery management system for charging or discharging a connected battery, and/or for use in a battery diagnostic method, using non-equilibrium potentials for one or more of the negative and positive electrodes determined for the battery, the battery management system comprising a processor configured to perform the steps of:
determining for a connected battery one or more battery state parameters indicating the present state of the connected battery, the battery state parameters including at least the instantaneous cell potential and the state-of-charge of the connected battery;
estimating for the connected battery, based upon the determined state-of-charge, one or more of: the battery open-circuit potential, and the open-circuit electrode potentials for the negative and/or positive electrodes;
determining the overpotentials for the one or more of the positive and negative electrodes of the connected battery, based on the estimated open-circuit potential for the reference battery, by referring to a reference overpotential fraction representation that is available in memory and which maps the respective state-of-charge values for the reference battery to the corresponding fractions of the battery overpotential that are attributable to the negative and the positive electrodes;
determining the non-equilibrium electrode potentials for the one or more of the negative and positive electrodes of the connected battery, based on the estimated open-circuit potential of the negative and/or positive electrodes of the reference battery, and the overpotentials for the respective negative and/or positive electrode;
controlling the charging or discharging of the battery, or determining one or more parameters indicative of battery health depending on the determined non-equilibrium potentials for the one or more of the negative and positive electrodes.

(11) Further, the system of note (10), wherein estimating one or more of the battery open-circuit potential, and the open-circuit electrode potentials for the negative and/or positive electrodes, comprises: based upon the determined state-of-charge for the connected battery, referring to a reference open-circuit potential representation that is available in memory, which maps the respective state-of-charge values for a reference battery to the corresponding values of open-circuit potential for the reference battery, and for the negative and positive electrodes of the reference battery.

(12) Further, the system of note (10) or (11), wherein determining the non-equilibrium electrode potentials for the one or more of the negative and positive electrode potentials comprises summing (S914) the open-circuit electrode potentials for the negative and positive electrodes with the overpotentials for the negative and positive electrodes.

(13) Further, the system of note (10), (11) or (12), wherein determining the overpotentials for the one or more of the negative and/or positive electrodes comprises combining (912) a value for the battery overpotential with an overpotential fraction value indicating the respective fractions of the battery overpotential attributable to the negative and the positive electrodes.

(14) Further, the system of note (13), wherein determining (S906) the battery overpotential comprises determining (S906) the difference between the determined cell potential for the connected battery and the open-circuit potential for the reference battery.

(15) Further, the system of any preceding note, wherein the battery state parameters further include one or more of battery temperature, charging current, and state-of-health.

(16) Further, the system of any preceding note, wherein reference open-circuit potential representations and reference overpotential fraction representations are determined for a plurality of different reference batteries and stored in memory.

(17) Further, the system of any preceding note, wherein the processor is configured to generate the open-circuit potential representation by monitoring the electrode potentials of a reference battery or a half cell reference battery for a range of state-of-charge values.

(18) Further, the system of any preceding note wherein the determined state-of-charge for the connected battery is used in place of the state-of-charge of the reference battery to look up the corresponding values in the open-circuit representation or the overpotential representation.

(19) In a third aspect, there is provided a computer readable medium having computer code stored thereon, which when executed by a computer causes the computer to perform the steps of any of notes (1) to (9).

1. A battery management method for charging or discharging a connected battery, using calculated non-equilibrium potentials for one or more of the negative and positive electrodes of the battery and one or more electrode potential set points the battery management method comprising the steps of:
determining for a connected battery one or more battery state parameters indicating the present state of the connected battery, the battery state parameters including one or more of the instantaneous battery potential, the battery current, and the battery temperature;
receiving an indication of electrode potential set points for the negative electrode potential and the positive electrode potential of the connected battery, the electrode potential set points including a maximum and a minimum electrode potential set point defining the range of electrode potential operating values for the negative electrode and positive electrode;
determining an instantaneous negative electrode potential and an instantaneous positive electrode potential for the connected battery based on a determined state of charge for the connected battery and an over potential fraction map, wherein the overpotential fraction map maps respective state-of-charge values for a reference battery to the corresponding fractions of the battery overpotential that are attributable to the negative and the positive electrodes; and
controlling a charging/discharging current for the connected battery, or controlling a charging/discharging voltage for the connected battery based on the determined instantaneous negative electrode potential and the instantaneous positive electrode potential, such that the determined instantaneous negative electrode potential and the instantaneous positive electrode potential remain within a range of electrode potential operating values defined by the received indication of one or more electrode potential set points.

2. The battery management method of claim 1, comprising:
maintaining the positive electrode potential, during the controlling a charging/discharging step, at a constant maximum electrode potential, equal to the maximum positive electrode potential set point; and/or
maintaining the negative electrode potential, during the controlling a charging/discharging step, at a constant minimum electrode potential, equal to a minimum negative electrode potential set point during the discharging/charging process.

3. The battery management method of claim 1, comprising:
calculating a positive electrode error as the difference between the positive electrode potential set point and a determined actual positive electrode potential value;
calculating a negative electrode potential as the difference between the negative electrode set point and a determined actual negative potential set point;
determining a combined error signal, combining the positive electrode error and the negative electrode error signals; and
determining, in the charging/discharging step, a charge or discharge current to bring the combined error closer to zero.

4. The battery management method of claim 1, comprising:
receiving an indication of one or more further set points, including a temperature set point for the connected battery, a battery current, and/or a battery potential.

5. The battery management method of claim 1, wherein receiving an indication of one or more electrode potential set points includes selecting a desired charging/discharging mode for the connected battery, the desired charging/discharging modes for the connected battery including:
a mode to minimize degradation of the battery positive and negative electrodes;
a mode to minimize battery charging time and/or maximise battery charging current; and
a mode to maximize charge and/or discharge power.

6. The battery management method of claim 4, wherein different set points are set for the different charging/discharging modes, the differences including the magnitudes of the maximum and minimum set points, as well as the magnitude of the range of electrode potential operating values.

7. The battery management method of claim 5, including setting the maximum and minimum electrode potential set points for the respective positive and negative electrodes in a narrower range for battery health modes, compared with the range for the maximum and minimum set points for battery charging/discharging performance modes.

8. The battery management method of claim 1, wherein one or more of the determined negative and positive electrode potential is used as a state-of-available-power indicator for the connected battery.

9. The battery management method of claim 8, wherein the value for state-of-available-power is calculated based on any two of the following four equations:
$$Equation 1 :$$
$$\{ \begin{matrix}{P}_{dch} = {V}_{pos , min} \cdot \frac{{U}_{pos} - {V}_{pos , min}}{{R}_{cell , dch}} & ( 1.1 ) \\ {P}_{chr} = {V}_{pos , max} \cdot \frac{{V}_{pos , max} - {U}_{cell}}{{R}_{cell , chr}} & ( 1.2 )\end{matrix}$$
$$Equation 2 :$$
$$\{ \begin{matrix}{P}_{dch} = {V}_{neg , min} \cdot \frac{{U}_{neg} - {V}_{neg , min}}{{R}_{cell , dch}} & ( 2.1 ) \\ {P}_{chr} = {V}_{neg , max} \cdot \frac{{V}_{neg , max} - {U}_{cell}}{{R}_{cell , chr}} & ( 2.2 )\end{matrix}$$
where the P_{dch} is the state of available power for discharge, P_{chr} is the state of available power for charge, V_{cell,min} is the minimum cell terminal voltage set point, V_{cell,min} is the maximum cell terminal voltage set point, U_{cell} is the terminal open-circuit potential, Uₚₒₛ is the positive terminal open-circuit potential, U_{neg} is the negative open-circuit potential, R_{cell,dch} is the battery impedance during discharge, R_{cell,chr} is the battery impedance during charge, V_{pos,max} is the maximum positive electrode potential setpoint, V_{pos,min} is the minimum electrode potential setpoint, V_{neg,max} is the maximum negative electrode potential setpoint, and V_{neg,min} is the minimum negative electrode potential setpoint.

10. A battery management system for charging or discharging a connected battery, using calculated non-equilibrium potentials for one or more of the negative and positive electrodes of the battery and one or more electrode potential set points the battery management system comprising:
a measurement module for determining for a connected battery one or more battery state parameters indicating the present state of the connected battery, the battery state parameters including one or more of the instantaneous battery potential, the battery current, and the battery temperature;
a set points module for receiving an indication of electrode potential set points for the negative electrode potential and the positive electrode potential of the connected battery, the electrode potential set points including a maximum and a minimum electrode potential set point defining the range of electrode potential operating values for the negative electrode and positive electrode;
a battery state estimator module for determining an instantaneous negative electrode potential and an instantaneous positive electrode potential for the connected battery based on a determined state of charge for the connected battery and an over potential fraction map, wherein the overpotential fraction map maps respective state-of-charge values for a reference battery to the corresponding fractions of the battery overpotential that are attributable to the negative and the positive electrodes; and
a control module for controlling a charging/discharging current for the connected battery, or controlling a charging/discharging voltage for the connected battery based on the determined instantaneous negative electrode potential and the instantaneous positive electrode potential, such that the determined instantaneous negative electrode potential and the instantaneous positive electrode potential remain within a range of electrode potential operating values defined by the received indication of one or more electrode potential set points.

11. The battery management system of claim 10, wherein the control module is configured to:
maintain the positive electrode potential, during the controlling a charging/discharging step, at a constant maximum electrode potential, equal to the maximum positive electrode potential set point, and/or
maintain the negative electrode potential, during the controlling a charging/discharging step, at a constant minimum electrode potential, equal to a minimum negative electrode potential set point during the discharging/charging process.

12. The battery management system of claim 10, wherein the control module is configured to:
calculate a positive electrode error as the difference between the positive electrode potential set point and a determined actual positive electrode potential value;
calculate a negative electrode potential as the difference between the negative electrode set point and a determined actual negative potential set point;
determine a combined error signal, combining the positive electrode error and the negative electrode error signals; and
determine, in the charging/discharging step, a charge or discharge current to bring the combined error closer to zero.

13. The battery management system of claim 10, wherein:
the set points module is configured to receive an indication of one or more further set points, including a temperature set point for the connected battery, a battery current, and/or a battery potential.

14. The battery management system of claim 10, wherein the set points module is configured to receive an indication of one or more electrode potential set points includes selecting a desired charging/discharging mode for the connected battery, wherein the desired charging/discharging modes for the connected battery include:
a mode to minimize degradation of the battery positive and negative electrodes;
a mode to minimize battery charging time and/or maximise battery charging current; and
a mode to maximize charge and/or discharge power.

15. The battery management system of claim 13, wherein the set points module sets different set points for the different charging/discharging modes, the differences including the magnitudes of the maximum and minimum set points, as well as the magnitude of the range of electrode potential operating values.

16. The battery management system of claim 15, wherein the control module is configured to set the maximum and minimum electrode potential set points for the respective positive and negative electrodes in a narrower range for battery health modes, compared with the range for the maximum and minimum set points for battery charging/discharging performance modes.

17. The battery management system of claim 10, wherein one or more of the determined negative and positive electrode potential is used as a state-of-available-power indicator for the connected battery.

18. The battery management system of claim 17, wherein the value for state-of-available-power is calculated based on any two of the following four equations:
$$Equation 1 :$$
$$\{ \begin{matrix}{P}_{dch} = {V}_{pos , min} \cdot \frac{{U}_{pos} - {V}_{pos , min}}{{R}_{cell , dch}} & ( 1.1 ) \\ {P}_{chr} = {V}_{pos , max} \cdot \frac{{V}_{pos , max} - {U}_{cell}}{{R}_{cell , chr}} & ( 1.2 )\end{matrix}$$
$$Equation 2 :$$
$$\{ \begin{matrix}{P}_{dch} = {V}_{neg , min} \cdot \frac{{U}_{neg} - {V}_{neg , min}}{{R}_{cell , dch}} & ( 2.1 ) \\ {P}_{chr} = {V}_{neg , max} \cdot \frac{{V}_{neg , max} - {U}_{cell}}{{R}_{cell , chr}} & ( 2.2 )\end{matrix}$$
where the P_{dch} is the state of available power for discharge, P_{chr} is the state of available power for charge, V_{cell,min} is the minimum cell terminal voltage set point, V_{cell,min} is the maximum cell terminal voltage set point, U_{cell} is the terminal open-circuit potential, Uₚₒₛ is the positive terminal open-circuit potential, U_{neg} is the negative open-circuit potential, R_{cell,dch} is the battery impedance during discharge, R_{cell,chr} is the battery impedance during charge, V_{pos,max} is the maximum positive electrode potential setpoint, V_{pos,min} is the minimum electrode potential setpoint, V_{neg,max} is the maximum negative electrode potential setpoint, and V_{neg,min} is the minimum negative electrode potential setpoint.

19. A computer implemented battery management diagnostic method using non-equilibrium potentials for one or more of the negative and positive electrodes determined for the battery, the battery management method comprising the steps of:
determining for a connected battery one or more battery state parameters indicating the present state of the connected battery, the battery state parameters including at least the instantaneous cell potential and the state-of-charge of the connected battery;
estimating for the connected battery, based upon the determined state-of-charge, one or more of the battery open-circuit potential and the open-circuit electrode potentials for the negative and/or positive electrodes;
determining the overpotentials for the one or more of the positive and negative electrodes of the connected battery, based on the estimated open-circuit potential for the reference battery, by referring to a reference overpotential fraction representation that is available in memory and which maps the respective state-of-charge values for the reference battery to the corresponding fractions of the battery overpotential that are attributable to the negative and the positive electrodes;
determining the non-equilibrium electrode potentials for the one or more of the negative and positive electrodes of the connected battery, based on the estimated open-circuit potential of the negative and/or positive electrodes of the reference battery, and the overpotentials for the respective negative and/or positive electrode; and
determining one or more parameters indicative of battery health depending on the determined non-equilibrium potentials for the one or more of the negative and positive electrodes,
wherein one or more of the determined negative and positive electrode potential is used as a state-of-available-power indicator for the connected battery.

20. The computer implemented method of claim 19, wherein the value for state-of-available-power is calculated based on any two of the following four equations:
$$Equation 1 :$$
$$\{ \begin{matrix}{P}_{dch} = {V}_{pos , min} \cdot \frac{{U}_{pos} - {V}_{pos , min}}{{R}_{cell , dch}} & ( 1.1 ) \\ {P}_{chr} = {V}_{pos , max} \cdot \frac{{V}_{pos , max} - {U}_{cell}}{{R}_{cell , chr}} & ( 1.2 )\end{matrix}$$
$$Equation 2 :$$
$$\{ \begin{matrix}{P}_{dch} = {V}_{neg , min} \cdot \frac{{U}_{neg} - {V}_{neg , min}}{{R}_{cell , dch}} & ( 2.1 ) \\ {P}_{chr} = {V}_{neg , max} \cdot \frac{{V}_{neg , max} - {U}_{cell}}{{R}_{cell , chr}} & ( 2.2 )\end{matrix}$$
where the P_{dch} is the state of available power for discharge, P_{chr} is the state of available power for charge, V_{cell,min} is the minimum cell terminal voltage set point, V_{cell,min} is the maximum cell terminal voltage set point, U_{cell} is the terminal open-circuit potential, Uₚₒₛ is the positive terminal open-circuit potential, U_{neg} is the negative open-circuit potential, R_{cell,dch} is the battery impedance during discharge, R_{cell,chr} is the battery impedance during charge, V_{pos,max} is the maximum positive electrode potential setpoint, V_{pos,min} is the minimum electrode potential setpoint, V_{neg,max} is the maximum negative electrode potential setpoint, and V_{neg,min} is the minimum negative electrode potential setpoint.

21. (canceled)
